(19) United States
(12) Patent Application Publication
(10) Pub. No.: US 2025/0321488 A1
(43) Pub. Date: Oct. 16, 2025

(54) CHEMICAL SOLUTION AND CHEMICAL SOLUTION-HOUSING ARTICLE

(71) Applicant: FUJIFILM CORPORATION, Tokyo (JP)

(72) Inventors: Tetsuya Kamimura, Shizuoka (JP); Akihiko Ohtsu, Shizuoka (JP); Ryo Saito, Shizuoka (JP)

(21) Appl. No.: 19/247,891

(22) Filed: Jun. 24, 2025

Related U.S. Application Data
(63) Continuation of application No. PCT/JP2023/040506, filed on Nov. 10, 2023.

(30) Foreign Application Priority Data
Jan. 10, 2023 (JP) 2023-001489

(51) Int. Cl. G03F 7/32

(52) U.S. Cl. CPC G03F 7/325

(57) ABSTRACT

It is an object of the present invention to provide a chemical solution that, when used as a developer or a rinsing liquid for a metal resist film, exhibits a high ability to suppress the occurrence of defects originating from alkali metal elements and/or alkaline-earth metals and the occurrence of defects originating from boron atoms and also exhibits a high pattern resolution. It is another object of the invention to provide a chemical solution-housing article that houses the chemical solution.

The chemical solution of the invention is a chemical solution containing propylene glycol monomethyl ether acetate and an organic acid. The content of the organic acid is 1% by mass or more and less than 40% by mass based on the total mass of the chemical solution, and the content of boron atoms is 0.001 to 100 ppt by mass based on the total mass of the chemical solution.

### CROSS-REFERENCE TO RELATED APPLICATIONS

This application is a Continuation of PCT International Application No. PCT/JP2023/040506 filed on Nov. 10, 2023, which claims priority under 35 U.S.C. § 119(a) to Japanese Patent Application No. 2023-001489 filed on Jan. 10, 2023. The above applications are hereby expressly incorporated by reference, in their entirety, into the present application.

### BACKGROUND OF THE INVENTION

### 1. Field of the Invention

The present invention relates to a chemical solution and a chemical solution-housing article.

### 2. Description of the Related Art

Conventional processes for producing semiconductor devices such as ICs (Integrated Circuits) and LSI (Large Scale Integrated) circuits involve lithographic microfabrication using a photoresist composition. In recent years, as the degree of integration of integrated circuits has increased, there has been a growing demand for ultra-fine pattern formation in the sub-micron or quarter-micron range. Accordingly, the wavelength of exposure light tends to be shortened. Specifically, the g-line is replaced by the i-line and further by KrF excimer laser light. Moreover, at present, in addition to the use of excimer laser light, lithography using electron beams, X-rays, EUV (extreme ultraviolet) rays, etc. is being developed.

In the lithography described above, a film (resist film) is formed using an actinic ray-sensitive or radiation-sensitive composition (which is referred to also as a “resist composition”), and then the obtained film is subjected to the following treatment. Specifically, the film is exposed to light and developed using a developer, and the developed film is washed with a rinsing liquid.

As the developer used for the lithography described above, JP2022-526031A, for example, discloses a developer composition used for developing treatment for an organometallic patterning layer. This developer composition contains a solvent having a value of Hansen solubility parameters δH+δP of about 16 (J/cm³)^{1/2} or less in an amount of at least 55% by volume and a solvent having a value of Hansen solubility parameters δH+δP of about 16 (J/cm³)^{1/2} in an amount of at least 0.25 to 45% by volume.

### SUMMARY OF THE INVENTION

In recent years, there is a growing demand for a further reduction in size of patterns formed and for a further reduction in the occurrence of defects in objects to be treated due to the reduction in size of the patterns.

The present inventors have conducted studies on chemical solutions used to form metal-containing resist patterns with reference made to JP2022-526031A. The inventors have found that there is room for further improvement in pattern resolution and in reducing the occurrence of defects, particularly in reducing the occurrence of defects originating from alkali metal elements and/or alkaline-earth metals and the occurrence of defects originating from boron atoms.

Accordingly, it is an object of the invention to provide a chemical solution that, when used as a developer or a rinsing liquid for a metal resist film, exhibits a high ability to suppress the occurrence of defects originating from alkali metal elements and/or alkaline-earth metals and the occurrence of defects originating from boron atoms and also exhibits a high pattern resolution.

It is another object of the invention to provide a chemical solution-housing article that houses the chemical solution.

The inventors have conducted extensive studies to solve the foregoing problem and found that the problem can be solved by the following aspects.

[1]A chemical solution including: propylene glycol monomethyl ether acetate; and an organic acid, wherein a content of the organic acid is 1% by mass or more and less than 40% by mass based on a total mass of the chemical solution, and wherein a content of boron atoms is 0.001 to 100 ppt by mass based on the total mass of the chemical solution.

[2] The chemical solution according to [1], wherein a total content of the propylene glycol monomethyl ether acetate and the organic acid is 98% by mass or more based on the total mass of the chemical solution.

[3] The chemical solution according to [1] or [2], wherein a total content of the propylene glycol monomethyl ether acetate and the organic acid is 99.5% by mass or more based on the total mass of the chemical solution.

[4] The chemical solution according to any one of [1] to [3], wherein the organic acid includes at least one selected from the group consisting of formic acid, acetic acid, propionic acid, butyric acid, glycolic acid, and lactic acid.

[5] The chemical solution according to any one of [1] to [4], further including Pb atoms, wherein a content of the Pb atoms is 0.001 to 10 ppt by mass based on the total mass of the chemical solution.

[6] The chemical solution according to any one of [1] to [5], further including water, wherein a content of the water is 0.0001 to 0.01% by mass based on the total mass of the chemical solution.

[7] The chemical solution according to any one of [1] to [6], wherein the content of the boron atoms is 0.05 to 50 ppt by mass based on the total mass of the chemical solution.

[8] The chemical solution according to any one of [1] to [7], wherein the content of the organic acid is 2 to 30% by mass based on the total mass of the chemical solution.

[9] The chemical solution according to any one of [1] to [8], wherein the chemical solution is used as a developer or a rinsing liquid.

[10]A chemical solution-housing article including: a container; and the chemical solution according to any one of [1] to [9], the chemical solution being housed in the container.

[11] The chemical solution-housing article according to [10], wherein the container has a liquid-contacting portion that is in contact with the chemical solution and that is formed of a nonmetallic material or stainless steel.

[12] The chemical solution-housing article according to [10] or [11], wherein the nonmetallic material is at least one selected from the group consisting of polyethylene resins, polypropylene resins, polyethylene-polypropylene resins, tetrafluoroethylene resins, tetrafluoroethylene-perfluoroalkyl vinyl ether copolymers, tetrafluoroethylene-hexafluoropropylene copolymer resins, tetrafluoroethylene-ethylene copolymer resins, chlorotrifluoroethylene-ethylene copolymer resins, vinylidene fluoride resins, chlorotrifluoroethylene copolymer resins, and vinyl fluoride resins.

The present invention can provide a chemical solution that, when used as a developer or a rinsing liquid for a metal resist film, exhibits a high ability to suppress the occurrence of defects originating from alkali metal elements and/or alkaline-earth metals and the occurrence of defects originating from boron atoms and also exhibits a high pattern resolution.

The present invention can also provide a chemical solution-housing article that houses the chemical solution.

### DESCRIPTION OF THE PREFERRED EMBODIMENTS

The present invention will next be described in detail.

The structural requirements described below may be described on the basis of representative embodiments of the present invention. However, the invention is not limited to these embodiments.

In the present specification, a numerical range represented using “to” means a range including the numerical values before and after the “to” as the lower limit and the upper limit, respectively.

In the present specification, “actinic rays” or “radiation” means, for example, an emission line spectrum of a mercury lamp, far-ultraviolet rays typified by excimer laser light, extreme ultraviolet light (EUV light), X-rays, electron beams (EB), etc. In the present specification, “light” means actinic rays or radiation.

In the present specification, “exposure to light” is intended to encompass not only exposure to an emission line spectrum of a mercury lamp, far-ultraviolet rays typified by excimer laser light, X-rays, EUV light, etc. but also image drawing using an electron beam or a particle beam such as an ion beam.

A substituent is preferably a monovalent substituent unless otherwise specified.

In the present specification, no limitation is imposed on the bonding direction of a divalent group, unless otherwise specified. For example, when Y in a compound represented by a formula “X-Y-Z” is —COO—, Y may be —CO—O— or may be —O—CO—. This compound may be “X—CO—O—Z” or may be “X—O—CO—Z.”

In the present specification, a halogen atom is, for example, a fluorine atom, a chlorine atom, a bromine atom, or an iodine atom.

In the present specification, solids mean components forming a metal resist film and do not include a solvent (such as an organic solvent or water). Any component included in a metal resist film is regarded as a solid even when it is in a liquid form.

In the present specification, when two or more types of component are present, the “content” of the component means the total content of the two or more types of component.

In the present specification, “ppm” means “parts-per-million (10⁻⁶),” and “ppb” means “parts-per-billion (10⁻⁹).” “ppt” means “parts-per-trillion (10⁻¹²).”

The chemical solution of the invention, the chemical solution-housing article of the invention, a pattern forming method, and an electronic device production method will be described successively.

### [Chemical Solution]

The chemical solution of the invention will be described in detail.

The chemical solution of the invention is a chemical solution containing propylene glycol monomethyl ether acetate (PGMEA) and an organic acid. The content of the organic acid is 1% by mass or more and less than 40% by mass based on the total mass of the chemical solution, and the content of boron atoms is 0.001 to 100 ppt by mass based on the total mass of the chemical solution.

The reason that the chemical solution having the composition described above can solve the problem in the invention is not always clear. However, the inventors infer that the reason is as follows.

The following inference does not limit the mechanism that produces the above-described effects. In other words, even when the effects are obtained through a mechanism other than the following mechanism, this mechanism is included in the scope of the invention.

The chemical solution contains PGMEA, which is an organic solvent having the ability to dissolve a metal resist in unexposed portions, and the prescribed amount of the organic acid that facilitates the dissolution of the metal resist in the unexposed portions and therefore exhibits a high pattern resolution. One feature of the chemical solution of the invention is that the content of boron atoms is 0.001 to 100 ppt by mass based on the total mass of the chemical solution. If the content of boron atoms in the chemical solution is more than 100 ppt by mass, residues of compounds containing boron atoms are generated, and the residues can form defects in an object to be treated. The compounds containing boron atoms may easily form salts with metals (such as alkali metals and alkaline-earth metals) that can be present in the chemical solution. When the content of boron atoms in the chemical solution is 0.001 ppt by mass or more, metals that can be present in the chemical solution can be easily removed as metal salts, and this may be the reason that the occurrence of defects in the object to be treated is suppressed. Because of the mechanism described above, the occurrence of defects originating from alkali metal elements and/or alkaline-earth metals (which are hereinafter referred to also as “specific elements”) and the occurrence of defects originating from boron atoms can be suppressed when the chemical solution is used as a developer or a rinsing liquid for a metal resist film.

The phrase “the effects of the invention are higher” means that at least one of the ability to suppress the occurrence of defects originating from alkali metal elements and/or alkaline-earth metals, the ability to suppress the occurrence of defects originating from boron atoms, or the pattern resolution is higher.

### [PGMEA]

The chemical solution contains PGMEA.

The content of PGMEA is preferably 60% by mass or more, more preferably 65% by mass or more, still more preferably 70% by mass or more, and particularly preferably 80% by mass or more based on the total mass of the chemical solution because a higher pattern resolution can be obtained. The upper limit of the content of PGMEA is less than 99% by mass, preferably less than 97% by mass, and still more preferably less than 95% by mass.

### [Organic Acid]

The chemical solution contains an organic acid, and the content of the organic acid is 1% by mass or more and less than 40% by mass based on the total mass of the chemical solution.

When the content of the organic acid is within the above range, it is inferred that the chemical solution obtained exhibits a higher pattern resolution and that performance deterioration before and after storage of the chemical solution, particularly deterioration of the pattern resolution after storage (which is hereinafter referred to as “storage stability”), is highly suppressed.

The organic acid is an organic compound having an acidic functional group and is acidic (its pH is less than 7.0) in an aqueous solution.

Examples of the organic acid contained in the chemical solution include carboxylic acids, sulfonic acids, sulfinic acids, organic phosphinic acids, and organic phosphonic acids. Of these, carboxylic acids or sulfonic acids are preferred, and carboxylic acids are more preferred.

The organic acid may be dissociated in the chemical solution or may form a salt.

Preferably, the organic acid has no boron atom in its molecule. In particular, the organic acid is preferably formed of a hydrocarbon residue optionally having a hydroxy group and a carboxy group or a sulfo group.

Examples of the hydrocarbon residue include aliphatic hydrocarbon residues and aromatic hydrocarbon residues, and aliphatic hydrocarbon residues are preferred. The number of carbon atoms in the organic acid is preferably 1 to 6 and more preferably 1 to 3.

The number of acidic groups (more preferably carboxy groups or sulfo groups) included in the organic acid is preferably 1 to 3 and more preferably 1 or 2.

Examples of the carboxylic acid include formic acid, acetic acid, propionic acid, butyric acid, pentanoic acid, hexanoic acid, glycolic acid, lactic acid, acrylic acid, methacrylic acid, oxalic acid, malonic acid, maleic acid, methyl malonic acid, fumaric acid, adipic acid, and phthalic acid. The carboxylic acid is preferably formic acid, acetic acid, propionic acid, butyric acid, glycolic acid, lactic acid, adipic acid, maleic acid, or phthalic acid, more preferably formic acid, acetic acid, propionic acid, butyric acid, glycolic acid, or lactic acid, and still more preferably acetic acid.

Examples of the sulfonic acid include methanesulfonic acid, ethanesulfonic acid, propanesulfonic acid, butanesulfonic acid, 2-hydroxyethanesulfonic acid, 3-hydroxypropanesulfonic acid, and benzenesulfonic acid. Of these, methanesulfonic acid or ethanesulfonic acid is preferred.

One organic acid may be used alone, or a combination of two or more may be used.

The content of the organic acid is preferably 2% by mass or more, more preferably 3% by mass or more, and still more preferably 5% by mass or more based on the total mass of the chemical solution because the effects of the invention are further improved.

The content of the organic acid is preferably 35% by mass or less, more preferably 30% by mass or less, still more preferably 20% by mass or less, and particularly preferably 18% by mass or less because the effects of the invention and/or storage stability is further improved.

The ratio of the content mass of the organic acid to the content mass of PGMEA (the content mass of the organic acid/the content mass of PGMEA) is preferably 0.01 to 0.8, more preferably 0.03 to 0.5, and still more preferably 0.05 to 0.4 because the effects of the invention and/or storage stability is further improved.

No particular limitation is imposed on the total content of PGMEA and the organic acid. The total content is preferably 95% by mass or more, more preferably 98% by mass or more, still more preferably 99.5% by mass or more, particularly preferably 99.9% by mass or more, and most preferably 99.99% by mass or more based on the total mass of the chemical solution. No particular limitation is imposed on the upper limit. The upper limit may be 100% by mass and is less than 100% by mass in many cases.

### [Boron Atoms]

The chemical solution of the invention contains boron atoms, and the content of boron atoms is 0.001 to 100 ppt by mass based on the total mass of the chemical solution.

The content of boron atoms is preferably 0.002 to 85 ppt by mass, more preferably 0.01 to 75 ppt by mass, still more preferably 0.05 to 50 ppt by mass, and particularly preferably 0.4 to 10 ppt by mass based on the total mass of the chemical solution because the effects of the invention are further improved.

No particular limitation is imposed on the form of boron atoms in the chemical solution. Examples of the form of boron atoms include boron-containing compounds such as inorganic boron compounds and organic boron compounds and elemental boron. The boron atoms may be present as ions in the chemical solution.

Examples of the inorganic boron compound include boric acid (H₃BO₃), borates, and metal borides.

In particular, the boron atoms are often in the form of boric acid or a borate. Examples of the borate include alkali metal salts such as a sodium salt and a potassium salt and alkaline-earth metal salts such as a calcium salt and a magnesium salt.

The boron atoms may be those intentionally added, may be those inevitably contained in the raw materials of the chemical solution, or may be those inevitably mixed during production, storage, and/or transportation of the chemical solution.

No particular limitation is imposed on the method for controlling the content of boron atoms. Examples of the method include a method in which boron atoms are removed from the chemical solution and/or the raw materials used to prepare the chemical solution, a method in which a component containing boron atoms (a boron atom source) is added, and a combination of these method.

Examples of the removal of boron atoms from the chemical solution and/or the raw materials used to prepare the chemical solution include removal of boron-containing compounds, elemental boron, ions containing boron, etc. from the chemical solution and/or the raw materials used to prepare the chemical solution.

In particular, a method in which a boron atom source is added to a mixture of the raw materials from which boron atoms have been removed is preferred because the composition can be easily controlled.

Any well-known boron atom removal method may be appropriately selected according to the form of boron atoms in the chemical solution and/or the raw materials used to prepare the chemical solution. Examples of the method include purification treatment such as ion removal treatment and filtration treatment described later, and anion exchange treatment is preferred.

No particular limitation is imposed on the boron atom source. For example, elemental boron and the boron-containing compounds described above can be used, and elemental boron, boric acid, and borates are preferred.

The content of boron atoms is measured by ICP-MS (inductively coupled plasma mass spectrometry).

Examples of the device used for ICP-MS include an Agilent 8900 triple quadrupole ICP-MS (inductively coupled plasma mass spectrometry for semiconductor analysis, option: #200) manufactured by Agilent Technologies Japan, Ltd., NexION 350S manufactured by PerkinElmer, and Agilent 8800 manufactured by Agilent Technologies Japan, Ltd.

When the content of boron atoms is measured, the measurement may be performed after the chemical solution is concentrated. The chemical solution is concentrated as follows.

A container used for concentration is a polytetrafluoroethylene-made container.

First, ultrapure water is added to the chemical solution to be subjected to quantification of boron atoms. The content of boron atoms in the ultrapure water is measured in advance. It is expected from a potential-pH diagram of a water-boron system that the boron is present in the form of boric acid in the ultrapure water.

Next, the chemical solution with the ultrapure water added thereto is heated to convert the boron present in the chemical solution to boric acid. Then the chemical solution subjected to the above heating treatment is concentrated.

When the chemical solution with the ultrapure water added thereto is heated, the chemical solution is heated at a temperature of 100° C. for 1 hour under reflux conditions.

When the concentration is performed, the organic solvent and water contained in the chemical solution are removed at 160 to 180° C.

When the content of boron atoms in the ultrapure water is measured, the measurement may be performed after the ultrapure water is concentrated.

During the concentration, the contents of boron atoms in chemical solutions with different concentration factors from 10 to 1000 are computed. When positive correlation (positive first-order correlation) is found between the concentration factor and the content of boron atoms, the contents of boron atoms contained in the chemical solutions can be quantified by the method described above.

### [Water]

The chemical solution may contain water.

No particular limitation is imposed on the water, and examples of the water include distilled water, ion exchanged water, pure water, and ultrapure water, and ultrapure water is preferred.

The water may be intentionally added water, may be water inevitably contained in the raw materials of the chemical solution, or may be water inevitably mixed during the production, storage, and/or transportation of the chemical solution.

No particular limitation is imposed on the method for controlling the water content. A method in which water is removed from the chemical solution and/or the raw materials used to prepare the chemical solution, a method in which water is added, or a combination of these methods may be used.

The method for removing water may be any well-known dewatering method, and examples include dewatering using a water adsorbent, distillation, and dewatering using a dewatering membrane.

Examples of the water adsorbent include zeolite (such as a molecular sieve), sodium sulfate, magnesium sulfate, silica gel, calcium chloride, anhydrous zinc chloride, fuming sulfuric acid, and soda lime.

Examples of the dewatering method using a dewatering membrane include membrane dewatering by pervaporation (PV) or vapor permeation (VP). Examples of the dewatering membrane include membranes formed of polymer-based materials such as polyimide-based, cellulose-based, and polyvinyl alcohol-based materials and membranes formed of inorganic-based materials such as zeolite.

The content of water is preferably 0.00001% by mass (0.1 ppm by mass) or more, more preferably 0.0001% by mass (1 ppm by mass) or more, still more preferably 0.0003% by mass (3 ppm by mass) or more, and particularly preferably 0.0005% by mass (5 ppm by mass) or more based on the total mass of the chemical solution.

The content of water is preferably 0.02% by mass (200 ppm by mass) or less, more preferably 0.01% by mass (100 ppm by mass) or less, still more preferably 0.008% by mass (80 ppm by mass) or less, and particularly preferably 0.005% by mass (50 ppm by mass) or less based on the total mass of the chemical solution because higher storage stability can be obtained.

The ratio of the content mass of the organic acid to the content mass of water (the content mass of the organic acid/the content mass of water) in the chemical solution is, for example, 100 to 200,000, preferably 300 to 100,000, more preferably 500 to 50,000, and still more preferably 1,000 to 10,000.

The content of water can be measured using a device that uses a Karl Fischer moisture measurement method as the measurement principle. The device used may be, for example, a Karl Fischer moisture meter (product name: “MKC-710M” manufactured by Kyoto Electronics Manufacturing Co., Ltd., Karl Fischer coulometric titration type).

### [Specific Metal Atoms]

The chemical solution may contain at least one type of metal atoms (hereinafter referred to also as “specific metal atoms”) selected from the group consisting of Pb (lead), Fe (iron), Cr (chromium), Ni (nickel), and Sn (tin).

Preferably, the specific metal atoms are Pb atoms.

The content of the specific metal atoms is preferably 0.0001 to 150 ppt by mass, more preferably 0.001 to 20 ppt by mass, and still more preferably 0.001 to 10 ppt by mass based on the total mass of the chemical solution.

Even when the specific metal atoms are Pb atoms, their content is preferably within the above range.

No particular limitation is imposed on the form of the specific metal atoms in the chemical solution. The specific metal atoms may be contained as metal particles or as metal ions.

The metal particles may be in the form of single substance particles composed of the specific metal atoms, in the form of particles of an alloy of the specific metal atoms and other metal atoms, or in the form of particles composed of the specific metal atoms combined with an organic substance. The metal ions may form a salt or a complex.

The specific metal atoms may be those intentionally added, may be those inevitably contained in the raw materials of the chemical solution, or may be those inevitably mixed during the production, storage, and/or transportation of the chemical solution.

No particular limitation is imposed on the method for controlling the content of the specific metal atoms. A method in which the specific metal atoms are removed from the chemical solution and/or the raw materials used to prepare the chemical solution, a method in which a component containing the specific metal atoms (a specific metal atom source) is added, or a combination of these methods may be used.

Examples of the removal of the specific metal atoms from the chemical solution and/or the raw materials used to prepare the chemical solution include removal of metal particles, metal ions, etc. from the raw materials.

In particular, a method in which a specific metal atom source is added to a mixture of the raw materials from which the specific metal atoms have been removed is preferred because the composition can be easily controlled.

To remove the specific metal atoms, any well-known method may be appropriately selected according to the form of the specific metal atoms in the chemical solution and/or the raw materials used to prepare the chemical solution. Examples of the method include purification treatment such as ion removal treatment and filtration treatment described later. When the specific metal atoms are in the form of metal particles, the filtration treatment is preferred. When the specific metal atoms are in the form of metal ions, the ion removal treatment is preferred.

No particular limitation is imposed on the specific metal atom source. Examples of the specific metal atom source include metal particles such as metal nanoparticles, metal oxide particles, and metal ion-containing compounds such as metal salts (e.g., metal halides) and organic metal complexes, and metal nanoparticles are preferred.

The type of specific metal atoms and their content can be measured by ICP-MS. The device that can be used for the ICP-MS is as described above.

When the type of specific metal atoms and their content are measured, the measurement may be performed after the chemical solution is concentrated. The chemical solution can be concentrated using the same procedure as the concentration procedure for measuring the content of boron atoms.

### [PGME]

The chemical solution may contain PGME.

The content of PGME is preferably 0.0001 to 1% by mass, more preferably 0.0005 to 0.5% by mass, and still more preferably 0.001 to 0.1% by mass based on the total mass of the chemical solution.

### [Additional Components]

The chemical solution may contain additional components other than the components described above.

Examples of the additional components include a surfactant.

The surfactant used may be any well-known surfactant, and examples include nonionic surfactants and fluorine-based surfactants.

Compounds exemplified in paragraph [0126] of WO2022/044893 can be used as the surfactant.

### <Organic Impurities Having Boiling Point of 250° C. Or Higher>

The chemical solution may contain organic impurities having a boiling point of 250° C. or higher (which may be hereinafter referred to also as “high-boiling point organic impurities”).

Examples of the high-boiling point organic impurities include, but are not limited to, dioctyl phthalate (boiling point: 385° C.), diisononyl phthalate (boiling point: 403° C.), dioctyl adipate (boiling point: 335° C.), dibutyl phthalate (boiling point: 340° C.), and ethylene propylene rubber (boiling point: 300 to 450° C.).

The content of the high-boiling point organic impurities is preferably 150 ppm by mass or less, more preferably 100 ppm by mass or less, and still more preferably 50 ppm by mass or less based on the total mass of the chemical solution. The lower limit of the content of the high-boiling point organic impurities is 0.001 ppm by mass or more and preferably 0.01 ppm by mass or more based on the total mass of the chemical solution.

The total content of the high-boiling point organic impurities in the chemical solution can be measured using a GCMS (gas chromatography mass spectrometry).

<Metal Atoms Other than Specific Metal Atoms>

In the chemical solution, the contents of metal atoms (such as Co, Na, Cu, Mg, Mn, Li, Al, and Ag) other than the specific metal atoms are each preferably 1000 ppt by mass or less and more preferably 500 ppt by mass or less. In the production of the most advanced semiconductor elements, it is expected that even higher purity chemical solutions are required. Therefore, the contents of the metal atoms other than the specific metal atoms are each more preferably less than 500 ppt by mass, particularly preferably 150 ppt by mass or less, and most preferably less than 100 ppt by mass. The lower limit is preferably 0.

Examples of the method for reducing the contents of the metal atoms other than the specific metal atoms include purification treatment such as filtration treatment, ion removal treatment, and distillation treatment described later.

Other examples include a method in which a container from which the dissolution of metal components is small is used as a container for storing the raw materials or the produced chemical solution and a method in which the inner walls of pipes used during the production of the chemical solution are lined with a fluorocarbon resin in order to prevent the dissolution of the metal components from the pipes.

### <Coarse Particles>

The chemical solution may contain coarse particles, but it is preferable that the content of the coarse particles is small.

The coarse particles mean particles having a diameter (particle size) of 1 μm or more when the shape of each particle is assumed to be spherical.

The coarse particles contained in the chemical solution are particles such as dust, dirt, organic solids, and inorganic solids that are contained in the raw materials as impurities and particles such as dust, dirt, organic solids, and inorganic solids that are brought into the chemical solution as contaminants during its preparation. The coarse particles do not dissolve in the final chemical solution and are present as particles.

As for the content of the coarse particles in the chemical solution, the number of particles with a diameter of 1 μm or more is preferably 100 or less per 1 μmL of the chemical solution and more preferably 50 or less per 1 mL of the chemical solution. The lower limit of the content is preferably 0.

The content of the coarse particles in the chemical solution can be measured in its liquid phase using a commercial measurement device that uses a laser as a light source and a light scattering type in-liquid particle measurement method.

Examples of the method for removing the coarse particles include purification treatment such as filtration treatment described later.

### [Production Method]

The chemical solution can be produced using any well-known method. For example, the chemical solution can be produced by mixing the components described above such that prescribed concentrations are obtained. No particular limitation is imposed on the order in which these components are mixed.

To remove excess portions of the components and/or impurities, the raw materials of the chemical solution and/or a mixture of the raw materials may be subjected to purification treatment. In particular, it is preferable that PGMEA, the organic acid, and PGME used to produce the chemical solution are products obtained by subjecting materials to be purified containing these components to purification treatment.

When a chemical solution containing boron atoms or the specific metal atoms described above in a prescribed amount is produced, it is preferable to produce the chemical solution containing the prescribed components as follows. Unpurified products containing the above-described components (PGMEA, the organic acid, and PGME) are subjected to purification treatment to reduce the amounts of components such as boron atoms and the specific metal atoms. Then prescribed amounts of boron atoms and/or the specific metal atoms are supplied to the resulting purified products or a solution mixture obtained by mixing the purified products. In this case, by subjecting the unpurified products containing the components used (PGMEA, the organic acid, and PGME) to purification treatment, the amount of components other than boron atoms and the specific metal atoms can also be reduced.

The unpurified products may be, for example, purchased or may be synthesized by reacting their precursors.

It is preferable that the content of impurities in the unpurified products is low. Examples of commercial products that meet this requirement include commercial products called “high purity grade products.”

No particular limitation is imposed on the method for synthesizing an unpurified product by reacting its precursor, and any well-known method can be used. In one exemplary method, one or more raw materials are reacted in the presence of a catalyst to obtain a reaction product, i.e., PGMEA.

For example, a method described in JP2011-509998A can be used as the method for synthesizing an unpurified product containing PGME.

In one method for synthesizing an unpurified product containing PGMEA, PGME and acetic acid used as raw materials are reacted in the presence of an acid catalysis. Specifically, for example, a method described in JP1984-176232A (JP-S59-176232A) and a method described in JP2001-521918A can be used.

When PGMEA is repeatedly subjected to ion removal treatment described later, the PGMEA may undergo a decomposition reaction. Therefore, it is preferable that a product subjected to ion removal treatment in advance is used as a raw material (specifically, PGME) used to synthesize an unpurified product containing PGMEA, and it is more preferable to use a raw material (PGME) from which boron atoms have been removed by anion exchange treatment.

To purify an unpurified product, any well-known method can be used. Examples of the purification method include filtration treatment, ion removal treatment, and distillation treatment.

To purify an unpurified product, a combination of a plurality of types of treatment selected from the group consisting of filtration treatment, ion removal treatment, and distillation treatment may be performed. For example, after primary purification in which an unpurified product is distilled, the resulting unpurified product may be subjected to secondary purification in which the unpurified product is caused to pass through an ion exchange resin and/or a filter. Alternatively, after primary purification in which an unpurified product is caused to pass through an ion exchange resin and/or a filter, the resulting unpurified product may be subjected to secondary purification in which the resulting unpurified product is distilled.

Each purification treatment may be repeated a plurality of times.

### <Filtration Treatment>

No particular limitation is imposed on the filtration treatment method, and any well-known method can be used. In particular, it is preferable to use filtration treatment in which an unpurified product is filtered using a filter. No particular limitation is imposed on the components removed by the filtration treatment, and examples of the components include metal particles and coarse particles.

No particular limitation is imposed on the filter used for the filtering, and any well-known filter can be used.

Examples of the material of the filter include fluorocarbon resins such as PTFE (polytetrafluoroethylene) and PFA (perfluoroalkoxyalkane), polyamide-based resins such as 6-nylon and 6,6-nylon, polyolefin resins (including high-density and ultrahigh-molecular weight polyolefin resins) such as polyethylene and polypropylene, diatomaceous earth, and glass. In particular, PTFE, polyamide-based resins, UPE (ultrahigh-density polyethylene), HDPE (high-density polyethylene), HDPP (high-density polypropylene), or UHDPP (ultrahigh-density polypropylene) is preferred. By using a filter formed of any of these materials, highly polar foreign substances and metallic impurities that are likely to cause particle defects can be removed more effectively.

The critical surface tension of the filter is preferably 70 to 95 mN/m and more preferably 75 to 85 mN/m. The value of the critical surface tension used may be the manufacturer's nominal value.

When the critical surface tension of the filter used is within the above range, highly polar foreign substances and metallic impurities that are likely to cause particle defects can be removed more effectively.

The pore diameter of the filter is preferably 0.1 nm to 1.0 μm, more preferably 0.5 nm to 0.1 μm, and still more preferably 1.0 to 50.0 nm. When the pore diameter of the filter is within the above range, fine foreign substances contained in the unpurified product can be removed effectively while clogging of the filter is prevented.

The filter may have been subjected to surface treatment. No particular limitation is imposed on the surface treatment method, and any well-known method can be used. Examples of the surface treatment include chemical modification treatment, plasma treatment, hydrophobic treatment, coating, gas treatment, and sintering. Of these, chemical modification treatment or plasma treatment is preferred.

The chemical modification treatment is preferably treatment in which ion exchange groups are introduced. Specifically, the filter may be an ion exchange filter.

Examples of the ion exchange group include: cation exchange groups such as a sulfonate group, a carboxy group, and a phosphate group; and anion exchange groups such as a quaternary ammonium group. No particular limitation is imposed on the method for introducing the ion exchange groups into the filter. In one exemplary method, a compound including an ion exchange group and a polymerizable group is reacted and grafted with a polymer contained in the filter.

The filtering may be multistage filtration treatment in which the unpurified product is caused to pass through two or more filters different in at least one selected from the group consisting of filter material, pore diameter, and pore structure. Alternatively, the unpurified product may be caused to pass through the same filter a plurality of times or may be caused to pass through a plurality of filters of the same type.

In particular, circulating filtration treatment is preferred in which a filtration device including a combination of a plurality of filters and a return passage is used to cause the unpurified product to pass through the filters a plurality of times.

No particular limitation is imposed on the number of times the circulating filtration is repeated. The number of repetitions may be appropriately selected according to the intended purity and impurities and is preferably 2 to 100, more preferably 20 to 80, and still more preferably 30 to 70.

No particular limitation is imposed on the number of filters used in combination, and the number of filters is preferably 1 to 10 and more preferably 2 to 5.

When the filtering is performed using a combination of different filters, it is preferable that the pore diameter of the filter that first comes into contact with the liquid is larger than or equal to the pore diameter of the filter that subsequently comes into contact with the liquid. The nominal value of each filter provided by the manufacturer can be used for the pore diameter of the filter.

Examples of the commercial filter include various filters available from Nihon Pall Ltd., Advantec Toyo Kaisha, Ltd., Nihon Entegris G. K., KITZ MICROFILTER CORPORATION, etc., and the filters used can be selected from these filters.

The temperature during filtering is preferably 25° C. or lower, more preferably 23° C. or lower, and still more preferably 20° C. or lower. The lower limit is preferably 0° C. or higher, more preferably 5° C. or higher, and still more preferably 10° C. or higher. When the temperature during filtering is within the above range, particulate foreign substances and impurities dissolved in the chemical solution precipitate and can be removed efficiently.

### <Ion Removal Treatment>

The ion removal treatment is treatment in which an unpurified product is subjected to ion exchange treatment or ion adsorption treatment using chelating groups. No particular limitation is imposed on the components removed by the ion removal treatment, but examples thereof include acids and metal ions.

No particular limitation is imposed on the ion exchange treatment method, and any well-known method can be used. Examples of the method include a method in which the unpurified product is brought into contact with an ion exchange resin. A method in which the unpurified product is caused to pass through a packed section packed with the ion exchange resin is preferred.

In the ion exchange treatment, the unpurified product may be caused to pass through the same ion exchange resin a plurality of times or may be caused to pass through different ion exchange resins.

Examples of the ion exchange resin include anion exchange resins and cation exchange resins.

When both a cation exchange resin and an anion exchange resin are used, the unpurified product may be caused to pass through a packed section packed with a resin mixture containing these resins or may be caused to pass through a plurality of packed sections packed with respective resins.

The anion exchange resin used may be any well-known anion exchange resin, and it is preferable to use a gel-type anion exchange resin.

Examples of the anion exchange resin include strongly basic anion exchange resins having quaternary ammonium groups and weakly basic anion exchange resins having amino groups.

The anion exchange resin used may be a commercial product, and examples thereof include: Amberlite IRA-400J, Amberlite IRA-410J, Amberlite IRA-900J, Amberlite IRA67, ORLITE DS-2, ORLITE DS-5, and ORLITE DS-6 (manufactured by Organo Corporation); DUOLITE A113LF, DUOLITE A116, and DUOLITE A-375LF (manufactured by Sumika Chemtex Co., Ltd.); and DIAION SA12A, DIAION SA10A, DIAION SA10AOH, DIAION SA20A, and DIAION WA10 (manufactured by Mitsubishi Chemical Corporation).

The anion exchange resin used may be an anion exchange resin described in JP2009-155208A.

The cation exchange resin used may be any well-known cation exchange resin and is preferably a gel-type cation exchange resin.

Specific examples of the cation exchange resin include sulfonic acid-type cation exchange resins and carboxylic acid-type cation exchange resins.

The cation exchange resin used may be a commercial product, and examples thereof include: Amberlite IR-124, Amberlite IR-120B, Amberlite IR-200CT, ORLITE DS-1, and ORLITE DS-4 (manufactured by Organo Corporation); DUOLITE C20J, DUOLITE C20LF, DUOLITE C255LFH, and DUOLITE C-433LF (manufactured by Sumika Chemtex Co., Ltd.); DIAION SK-110, DIAION SK1B, and DIAION SK1BH (manufactured by Mitsubishi Chemical Corporation); and Purolite S957 and Purolite S985 (manufactured by Purolite).

No particular limitation is imposed on the ion adsorption treatment using chelating groups, and any well-known method can be used. Examples of the ion adsorption treatment include a method in which the unpurified product is caused to pass through a packed section packed with a chelating resin having a chelating group.

In the ion removal treatment, the unpurified product may be caused to pass through the same chelating resin a plurality of times or may be caused to pass through different chelating resins.

Examples of the chelating resin include resins having a chelating ability or a chelating group such as an amidoxime group, a thiourea group, a thiouronium group, iminodiacetic acid, amidophosphoric acid, phosphonic acid, aminophosphoric acid, aminocarboxylic acid, N-methylglucamine, an alkylamino group, a pyridine ring, cyclic cyanine, a phthalocyanine ring, or a cyclic ether.

The ion removal treatment may be used in combination with the filtration treatment described above. For example, a method may be used in which a column packed with an ion exchange resin is installed in the circulating filtration device described above and the untreated product is caused to continuously pass through the ion exchange resin-packed section and the filter.

### <Distillation Treatment>

No particular limitation is imposed on the distillation treatment method, and any well-known method can be used. Examples of the method include a method using a distillation column. No particular limitation is imposed on the components removed by the distillation process, and examples include acids, organic compounds, and water.

No particular limitation is imposed on the liquid-contacting portion of the distillation column. It is preferable that the liquid-contacting portion is formed from a corrosion-resistant material. Examples of the corrosion-resistant material include materials used for a chemical solution-housing article described later.

In the distillation treatment, the unpurified product may be caused to pass through the same distillation column a plurality of times or may be caused to pass through different distillation columns.

When the unpurified product is caused to pass through different distillation columns, the following method, for example, may be used. The unpurified product is subjected to rough distillation treatment in which the unpurified product is caused to pass through a distillation column to remove low-boiling point acids etc. and then subjected to rectification treatment in which the resulting product is caused to pass through a distillation column different from the distillation column for the rough distillation treatment to remove acid components, other organic compounds, etc. Examples of the distillation column in the rough distillation treatment include a plate distillation column, and examples of the distillation column in the rectification treatment include a distillation column including at least one of a plate distillation column or a reduced pressure plate distillation column.

When the plate distillation column is used, the theoretical number of plates is preferably 50 or more and more preferably 100 or more. No particular limitation is imposed on the upper limit of the theoretical number of plates, but the number of plates is 200 or less in many cases. For the purpose of achieving both thermal stability during distillation and precision of purification, reduced-pressure distillation may be used.

The distillation treatment used may be combined with at least one selected from the above-described filtration treatment and the above-described ion removal treatment. For example, the following method may be used. A distillation column is disposed on the primary side of a purification device used for the filtration treatment to introduce the distilled unpurified product into the purification device.

### <Additional Purification Treatment>

Purification treatment other than those described above such as dewatering treatment may be performed.

The dewatering treatment may be, for example, the water removal method described above.

It is preferable to produce the chemical solution by the following method. An unpurified product containing PGME and an unpurified product containing acetic acid are prepared, and the materials to be purified are each subjected to purification treatment. Then the unpurified products subjected to the purification treatment are reacted to produce a liquid containing PGMEA. The PGMEA-containing liquid obtained and an unpurified product containing the organic acid and prepared separately are further subjected to purification treatment, and the resulting liquids subjected to the purification treatment are mixed to produce the chemical solution.

Preferably, the purification treatment includes at least the distillation treatment and the filtration treatment. In this case, no particular limitation is imposed on the order of the distillation treatment and the filtration treatment. The filtration treatment may be performed after the distillation treatment, or the distillation treatment may be performed after the filtration treatment.

In the filtration treatment, it is preferable to use at least one first filter selected from the group consisting of ion exchange filters and filters containing polyamide-based resins (such as Nylon filters) and at least one second filter selected from the group consisting of PTFE filters and UPE filters. The first filter can remove mainly ions, organic impurities etc., and the second filter can remove mainly particles (such as metal particles and organic particles) etc.

A plurality of first filters and a plurality of second filters may be used. In particular, it is preferable to use three or more second filters.

As described above, the filtration treatment performed may be circulating filtration treatment. The number of repetitions of the circulating filtration is as described above but is preferably 30 or more.

In the distillation treatment, it is preferable that the unpurified product is caused to pass through different distillation columns.

The amount of impurities contained in the raw materials of the chemical solution can be reduced to the detection limit or lower by the procedure described above, and the content of impurities in the chemical solution produced can thereby be reduced.

Boron contained in the chemical solution can be easily removed by the first filter.

### <Handling>

It is preferable that the handling and production of the chemical solution, the purification treatment, opening of a container of the chemical solution, washing of the container and devices, filling of the chemical solution, analysis, etc. are all performed in a clean room. Preferably, the cleanliness of the clean room is higher than or equal to class 4 defined in the international standard ISO 14644-1:2015 specified by the International Organization for Standardization. Specifically, the cleanliness of the clean room meets preferably ISO class 1, ISO class 2, ISO class 3, or ISO class 4, more preferably ISO class 1 or ISO class 2, or particularly preferably ISO class 1.

It is preferable that the handling, production, purification, housing, and storage of the chemical solution are performed at 30° C. or lower because the performance of the chemical solution can be maintained stably for a long time. The lower limit is preferably 5° C. or higher and more preferably 10° C. or higher.

### [Chemical Solution-Housing Article]

The chemical solution may be housed and stored in a container.

A combination of the container and the chemical solution housed in the container is referred to as a chemical solution-housing article.

The container may be purged in advance with an inert gas (such as nitrogen or argon) with a purity of 99.99995% by volume for the purpose of preventing deterioration of the components of the liquid during storage. The inert gas is preferably a gas with a small moisture content. The chemical solution may be transported and/or stored at room temperature. However, the temperature may be controlled in the range of −20° C. to 20° C. in order to prevent deterioration.

### [Container]

The container used to house the chemical solution may be any well-known container and is preferably a high-cleanliness container for semiconductor applications from which elution of impurities is low.

Examples of the container include the “Clean Bottle” series (manufactured by AICELLO CHEMICAL CO., LTD.) and “Pure bottles” (manufactured by KODAMA PLASTICS Co., Ltd.). From the viewpoint of preventing mixing of impurities (contaminants) into the raw materials and the chemical solution, it is also preferable to use a multilayer container in which its inner wall has a six-layer structure formed of six resins or a multilayer container having a seven-layer structure formed of seven resins.

Examples of the multilayer container include containers described in JP2015-123351A, the entire contents of which are incorporated herein by reference.

Liquid-contacting portions (such as the container inner wall, the inlet for the chemical solution, and the outlet for the chemical solution) of the container that are to be in contact with the chemical solution may be formed of a nonmetallic material or a metal material and are formed of preferably a nonmetallic material or stainless steel.

Preferably, the liquid-contacting portions are formed of a nonmetallic material in order to prevent contamination.

No particular limitation is imposed on the nonmetallic material, and any well-known material can be used. Examples of the nonmetallic material include polyethylene resins, polypropylene resins, polyethylene-polypropylene resins, tetrafluoroethylene resins, tetrafluoroethylene-perfluoroalkyl vinyl ether copolymers, tetrafluoroethylene-hexafluoropropylene copolymer resins, tetrafluoroethylene-ethylene copolymer resins, chlorotrifluoroethylene-ethylene copolymer resins, vinylidene fluoride resins, chlorotrifluoroethylene copolymer resins, and vinyl fluoride resins. Of these, fluorine-based resins are preferably used in order to prevent contamination.

Specific examples of the container whose inner wall is formed of a fluorine-based resin include FluoroPure PFA composite drums manufactured by Entegris. Containers described in page 4 etc. of JP1991-502677A (JPH03-502677A), page 3 etc. of WO2004/016526A, and pages 9 and 16 etc. of WO99/046309A can also be used.

When the inner wall is formed of a nonmetallic material, it is preferable that the elution of an organic component in the nonmetallic material into the liquid is suppressed.

The liquid-contacting portions may be formed of a metal material.

No particular limitation is imposed on the metal material. A metal material containing chromium in an amount of more than 25% by mass based on the total mass of the metal material is preferred. Examples of the metal material include stainless steel and nickel-chromium alloys, and stainless steel is preferred.

No particular limitation is imposed on the stainless steel, and any well-known stainless steel can be used. In particular, an alloy containing nickel in an amount of 8% by mass or more is preferred, and austenitic stainless steel containing nickel in an amount of 8% by mass or more is more preferred. Examples of the austenitic stainless steel include SUS (Steel Use Stainless) 304 (Ni content: 8% by mass, Cr content: 18% by mass), SUS 304L (Ni content: 9% by mass, Cr content: 18% by mass), SUS 316 (Ni content: 10% by mass, Cr content: 16% by mass), and SUS 316L (Ni content: 12% by mass, Cr content: 16% by mass).

No particular limitation is imposed on the nickel-chromium alloy, and any well-known nickel-chromium alloy can be used. Examples of the nickel-chromium alloy include Hastelloy (trade name, the same applies to the following), Monel (trade name, the same applies to the following), and Inconel (trade name, the same applies to the following). More specific examples include Hastelloy C-276 (Ni content: 63% by mass, Cr content: 16% by mass), Hastelloy-C(Ni content: 60% by mass, Cr content: 17% by mass), and Hastelloy C-22 (Ni content: 61% by mass, Cr content: 22% by mass).

The nickel-chromium alloy may optionally further contain, in addition to the alloying elements described above, silicon, tungsten, molybdenum, copper, cobalt, etc.

The above metal material may preferably have been electropolished and is more preferably electropolished stainless steel.

Any well-known electropolishing method can be used, and examples thereof include methods described in [0011] to [0014] of JP2015-227501A and in [0036] to [0042] of JP2008-264929A.

The metal material may have been buffed for the purpose of preventing contamination. No particular limitation is imposed on the buffing method, and any well-known method can be used. No particular limitation is imposed on the size of abrasive grains used for finish buffing. The abrasive grain size is preferably less than or equal to #400 because irregularities on the surface of the metal material can be more easily reduced. Preferably, the buffing is performed before electropolishing.

The metal material may have been subjected to one of or a combination of two or more of the following processes: buffing including a plurality of stages performed using different abrasive grains with different sizes, washing with acid, and magnetic fluid grinding.

Preferably, the inside of the container has been washed before the container is filled with the chemical solution. The liquid used for the washing is preferably the chemical solution described above or a solution obtained by diluting the chemical solution.

### [Pattern Forming Method]

The chemical solution of the invention can be used for the following pattern forming method.

The pattern forming method includes: step 1 of forming a metal resist film on a substrate using an actinic ray-sensitive or radiation-sensitive composition (which is hereinafter referred to also as a “metal resist composition”) containing a metal compound having at least one bond selected from the group consisting of a metal-carbon bond and a metal-oxygen bond (this metal compound is hereinafter referred to also as a “specific metal compound”); step 2 of exposing the metal resist film to light; and step 3 of subjecting the light-exposed metal resist film to developing treatment using a developer to remove unexposed portions to thereby obtain a pattern. The pattern forming method may further include, after step 3, step 4 of washing the pattern using a rinsing liquid.

Each of the steps will be described in detail.

### [Step 1]

Step 1 is the step of forming the metal resist film using the metal resist composition.

Examples of the method for forming the metal resist film using the metal resist composition include a method in which the metal resist composition is applied to a substrate and a method in which the metal resist composition is vapor-deposited on a substrate. The metal resist composition will be described later.

Examples of the method in which the metal resist composition is applied to a substrate include a method in which the metal resist composition is applied to a substrate (such as a silicon substrate) used to produce semiconductor devices such as integrated circuits using a device such as a spinner or a coater.

The coating method is preferably spin coating using a spinner. The rotation speed during spin coating is preferably 1000 to 3000 rpm.

The metal resist film may be formed by drying the substrate coated with the metal resist composition.

Examples of the drying method include heating (pre-baking). Means included with a well-known exposing device and/or a well-known developing device can be used for the heating, and a hot plate may be used.

The heating temperature is preferably 80 to 150° C., more preferably 80 to 140° C., and still more preferably 80 to 130° C. The heating time is preferably 30 to 1000 seconds, more preferably 30 to 800 seconds, and still more preferably 40 to 600 seconds. The heating may be repeated two or more times.

The thickness of the metal resist film is preferably 10 to 90 nm, more preferably 10 to 65 nm, and still more preferably 15 to 50 nm because a more precise and finer pattern can be formed.

An undercoat film (such as an inorganic film, an organic film, or an antireflection film) may be formed between the substrate and the metal resist film. The undercoat film can be formed using a well-known organic or inorganic material. Examples of a composition for forming the undercoat film include AL412 (manufactured by Brewer Science) and the SHB series (such as SHB-A940 manufactured by Shin-Etsu Chemical Co., Ltd.).

The thickness of the undercoat film is preferably 10 to 90 nm, more preferably 10 to 50 nm, and still more preferably 10 to 30 nm.

A topcoat may be formed on a surface of the metal resist film that is opposite from the substrate using a topcoat composition.

Preferably, the topcoat composition does not mix with the metal resist film and can be applied uniformly to the surface of the metal resist film that is opposite from the substrate.

Preferably, the topcoat composition contains a resin, an additive, and a solvent.

The method for forming the topcoat may be, for example, any well-known topcoat forming method, and specific examples include a topcoat forming method described in [0072] to [0082] of JP2014-059543A.

### <Metal Resist Composition>

The metal resist composition contains the specific metal compound.

The specific metal compound is a metal compound having at least one bond selected from the group consisting of a metal-carbon bond (M-C) and a metal-oxygen bond (M-0). M represents a metal.

The metal-carbon bond is a state in which a metal atom and at least one carbon atom are bonded through a covalent bond, a coordinate bond, an ionic bond, a van der Waals bond, etc. The covalent bond may be a single bond, a double bond, or a triple bond. The metal-oxygen bond is a state in which at least one metal atom and at least one oxygen atom in the specific metal compound are bonded through a covalent bond, a coordinate bond, an ionic bond, a van der Waals bond, etc. The covalent bond may be a single bond or a double bond.

When the specific metal compound has a metal-carbon bond, the specific metal compound is a so-called organometallic compound.

The number of bonds in the specific metal compound that are selected from the above group is preferably 2 or more and more preferably 3 or more. The upper limit of the number of bonds is preferably 10 or less and more preferably 5 or less.

Examples of the metal atom included in the specific metal compound include group 3 to group 15 metal atoms in the periodic table, and the metal atom is preferably tin, antimony, tellurium, indium, hafnium, tantalum, tungsten, bismuth, titanium, cobalt, nickel, zirconium, or palladium and is more preferably tin.

In the present specification, silicon atoms are classified as metal atoms.

Examples of the specific metal compound include a compound represented by formula (1).

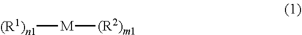

In formula (1), M represents a metal atom.

M is a metal atom included in the specific metal compound. The metal atom is preferably tin, antimony, tellurium, indium, hafnium, tantalum, tungsten, bismuth, titanium, cobalt, nickel, zirconium, or palladium and is more preferably tin.

In formula (1), R¹ represents an alkyl group optionally having a substituent, an unsaturated aliphatic hydrocarbon group optionally having a substituent, or an aryl group optionally having a substituent.

The alkyl group may be linear, branched, or cyclic.

The number of carbon atoms in the alkyl group is preferably 1 to 30, more preferably 1 to 16, and still more preferably 1 to 5. When the alkyl group represented by R¹ is an alkyl group having a substituent, the number of carbon atoms includes the number of carbon atoms in the substituent.

Examples of the optional substituent in the alkyl group include a halogen atom, a hydroxy group, a cyano group, a nitro group, an amino group, and aromatic ring groups. The aromatic ring group is preferably a phenyl group. The alkyl group having a phenyl group is preferably a benzyl group.

The unsaturated aliphatic hydrocarbon group is an aliphatic hydrocarbon group having an unsaturated group. Examples of the unsaturated group include a double bond and a triple bond.

The unsaturated aliphatic hydrocarbon group may be linear, branched, or cyclic.

The number of carbon atoms in the unsaturated aliphatic hydrocarbon group is preferably 2 to 30, more preferably 2 to 16, and still more preferably 2 to 5. When the unsaturated aliphatic hydrocarbon group represented by R¹ is an unsaturated aliphatic hydrocarbon group having a substituent, the number of carbon atoms includes the number of carbon atoms in the substituent.

The unsaturated aliphatic hydrocarbon group is preferably a vinyl group or an allyl group.

Examples of the optional substituent in the unsaturated aliphatic hydrocarbon group include halogen atoms, a hydroxy group, a cyano group, a nitro group, an amino group, and aromatic ring groups.

The aryl group may be monocyclic or may be polycyclic.

The number of carbon atoms in the aryl group is preferably 6 to 30, more preferably 6 to 12, and still more preferably 6 to 8. When the aryl group represented by R¹ is an aryl group having a substituent, the number of carbon atoms includes the number of carbon atoms in the substituent.

The aryl group is preferably a phenyl group or a naphthyl group.

Examples of the optional substituent in the aryl group include alkyl groups, halogen atoms, a hydroxy group, a cyano group, a nitro group, an amino group, and aromatic ring groups.

In formula (1), R² represents —OCOR^{r1} or —OR^{r2}. R^{r1} represents a hydrogen atom, an alkyl group optionally having a substituent, an unsaturated aliphatic hydrocarbon group optionally having a substituent, or an aryl group optionally having a substituent. R^{r2} represents an alkyl group optionally having a substituent, an unsaturated aliphatic hydrocarbon group optionally having a substituent, or an aryl group optionally having a substituent.

R² is preferably —OCOR^{r1}.

Examples of the alkyl group optionally having a substituent, the unsaturated aliphatic hydrocarbon group optionally having a substituent, and the aryl group optionally having a substituent that are represented by R^{r1} or R^{r2} include those of the groups represented by R¹ described above.

In formula (1), n1+m1 represents the valence of the metal atom represented by M, n1+m1 is appropriately selected according to the possible valence of the metal atom represented by M.
n1 is preferably an integer of 0 to 2 and more preferably 1.
m1 is preferably an integer of 0 to 4 and more preferably 3.

When a plurality of R¹ s are present, the R¹s may be the same or different. When a plurality of R²s are present, the R²s may be the same or different.

Other examples of the specific metal compound include a compound represented by formula (2) and condensates thereof.

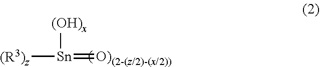

$$0 < z ≦ 2 \qquad ( 2 - 1 )$$

$$0 < z + x ≦ 4 \qquad ( 2 - 2 )$$

In formula (2), R³ represents a hydrocarbon group optionally having a substituent.

Examples of the hydrocarbon group include alkyl groups optionally having a substituent, unsaturated aliphatic hydrocarbon groups optionally having a substituent, and aryl groups optionally having a substituent. Preferred forms of the alkyl groups, the unsaturated aliphatic hydrocarbon groups, and the aryl groups are the same as the preferred forms of the groups represented by R¹.

When a plurality of R³s are present, the R³s may be the same or different.

z and x are numbers that satisfy the relation of formula (2-1) and the relation of formula (2-2).

Other examples of the specific metal compound include a compound represented by formula (3).

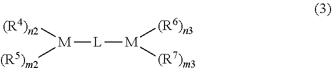

In formula (3), M represents a metal atom.

Examples of M include those of the metal atom represented by M in formula (1).

R⁴ and R⁶ each independently represent an alkyl group optionally having a substituent, an unsaturated aliphatic hydrocarbon group optionally having a substituent, or an aryl group optionally having a substituent.

Examples of R⁴ and R⁶ include those of the group represented by R¹ above.

R⁵ and R⁷ each independently represent —OCOR^{r3} or —OR^{r4}. R^{r3} represents a hydrogen atom, an alkyl group optionally having a substituent, an unsaturated aliphatic hydrocarbon group optionally having a substituent, or an aryl group optionally having a substituent. R^{r4} represents an alkyl group optionally having a substituent, an unsaturated aliphatic hydrocarbon group optionally having a substituent, or an aryl group optionally having a substituent.

Examples of R^{r3} and R^{r4} include those of the groups represented by R^{r1} and R^{r2}.

Examples of R⁵ and R⁷ include those of the group represented by R².

When a plurality of R⁴s are present, the R⁴s may be the same or different. When a plurality of R⁵s are present, the R⁵s may be the same or different. When a plurality of R⁶s are present, the R⁶s may be the same or different. When a plurality of R⁷s are present, the R⁷s may be the same or different.

L represents a single bond or a divalent linking group.

Examples of the divalent linking group include alkylene groups and arylene groups.

n2+m2 and n3+m3 each independently represent the valence of the metal atom represented by M−1.

Other examples of the specific metal compound include a compound represented by formula (4), hydrolysates thereof, and condensates of the hydrolysates.

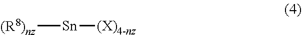

In formula (4), R⁸ represents a hydrocarbon group optionally having a substituent.

Examples of the hydrocarbon group include those of the group represented by R¹.

X represents a hydrolyzable group. nz represents 1 or 2.

Examples of X include —NHR^{x1}, —NR^{x1}R^{x2}, —OSiR^{x1}R^{x2}R^{x3}, —N(SiR^{x1}₃)(R^{x2}₃), —N(SiR^{x1}₃)(SiR^{x2}₃), an azido group, —C≡CR^{x1}, —NH(COR^{x1}), —NR^{x1}(COR^{x2}), —NR^{x1}C(NR^{x2})R^{x3} (an amidinate group), and an imido group, and —NHR^{x1} or —NR^{x1}R^{x2} is preferred. R^{x1} to R^{x3} each independently represent a hydrocarbon group having 1 to 10 carbon atoms. R^{x1} to R^{x3} are Each preferably an alkyl group having 1 to 10 carbon atoms.

When a plurality of R⁸s are present, the R⁸s may be the same or different. When a plurality of Xs are present, the Xs may be the same or different.

The specific metal compound is preferably a compound represented by formula (5).

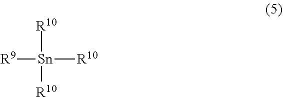

In formula (5), R⁹ represents an alkyl group optionally having a substituent, an unsaturated aliphatic hydrocarbon group optionally having a substituent, or an aryl group optionally having a substituent. R¹⁰ represents —OCOR^{r5} or —OR^{r6}. R^{r5} represents a hydrogen atom, an alkyl group optionally having a substituent, an unsaturated aliphatic hydrocarbon group optionally having a substituent, or an aryl group optionally having a substituent. R⁶ represents an alkyl group optionally having a substituent, an unsaturated aliphatic hydrocarbon group optionally having a substituent, or an aryl group optionally having a substituent.

R⁹, R¹⁰, R^{r5}, and R^{r6} are the same as R¹, R², R^{r1}, and R^{r2}, respectively, in formula (1), and their preferred forms are also the same as those of R¹, R², R^{r1}, and R^{r2} in formula (1).

The plurality of R¹⁰s present may be the same or different.

The specific metal compound includes preferably at least one selected from the group consisting of the compound represented by formula (1), the compound represented by formula (2), and condensates thereof, includes more preferably at least one selected from the group consisting of the compound represented by formula (5), the compound represented by formula (2), and condensates thereof, and includes still more preferably at least one selected from the group consisting of the compound represented by formula (2) and condensates thereof.

Other examples of the specific metal compound include specific metal compounds described in JP2021-047426A, JP2021-179606A, JP6805244B, and WO2019/111727A.

One specific metal compound may be used alone, or a combination of two or more may be used.

The content of the specific metal compound is preferably 50 to 100% by mass and more preferably 80 to 100% by mass based on the total solid amount of the metal resist composition.

### <Organic Acid>

The metal resist composition may contain an organic acid.

Examples of the organic acid include carboxylic acids, sulfonic acids, sulfinic acids, organic phosphinic acids, organic phosphonic acids, phenols, enols, thiols, imidic acids, oximes, and sulfonamides. Of these, carboxylic acids are preferred.

Examples of the carboxylic acid include: monocarboxylic acids such as formic acid, propionic acid, butanoic acid, pentanoic acid, hexanoic acid, heptanoic acid, octanoic acid, nonanoic acid, decanoic acid, 2-ethylhexanoic acid, oleic acid, acrylic acid, methacrylic acid, trans-2,3-dimethylacrylic acid, stearic acid, linoleic acid, linolenic acid, arachidonic acid, salicylic acid, benzoic acid, p-aminobenzoic acid, monochloroacetic acid, dichloroacetic acid, trichloroacetic acid, trifluoroacetic acid, pentafluoropropionic acid, gallic acid, and shikimic acid; dicarboxylic acids such as oxalic acid, malonic acid, maleic acid, methyl malonic acid, fumaric acid, adipic acid, sebacic acid, phthalic acid, and tartaric acid; and carboxylic acids having three or more carboxy groups such as citric acid.

One organic acid may be used alone, or a combination of two or more may be used.

The content of the organic acid is preferably 0 to 10% by mass and more preferably 1 to 5% by mass based on the total solid amount of the metal resist composition.

### <Organic Solvent>

The metal resist composition may contain an organic solvent. Examples of the organic solvent include ketone-based solvents, ester-based solvents, alcohol-based solvents, amide-based solvents, ether-based solvents, and hydrocarbon-based solvents.

Examples of the ketone-based solvent include 1-octanone, 2-octanone, 1-nonanone, 2-nonanone, acetone, 2-heptanone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, and propylene carbonate. Of these, cyclohexanone, 2-heptanone, or diisobutyl ketone is preferred.

Examples of the ester-based solvent include methyl acetate, butyl acetate, ethyl acetate, propyl acetate, isopropyl acetate, pentyl acetate, isopentyl acetate, hexyl acetate, ethylene glycol monoethyl ether acetate, diethylene glycol monobutyl ether acetate, diethylene glycol monoethyl ether acetate, ethyl-3-ethoxypropionate, 3-methoxybutyl acetate, 1-methoxy-2-propyl acetate, 3-methyl-3-methoxybutyl acetate, methyl formate, ethyl formate, butyl formate, propyl formate, ethyl lactate, butyl lactate, propyl lactate, butyl butyrate, methyl 2-hydroxyisobutyrate, isoamyl butyrate, isobutyl isobutyrate, ethyl propionate, propyl propionate, butyl propionate, and isobutyl propionate. Of these, propyl acetate, butyl acetate, hexyl acetate, ethyl lactate, isoamyl butyrate, ethyl propionate, propyl propionate, butyl propionate, or isobutyl propionate is preferred.

Examples of the alcohol-based solvent include methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, 4-methyl-2-pentanol, n-heptyl alcohol, n-octyl alcohol, n-decanol, ethylene glycol, diethylene glycol, triethylene glycol, propylene glycol, ethylene glycol monomethyl ether, ethylene glycol monoethyl ether, propylene glycol monoethyl ether, diethylene glycol monomethyl ether, triethylene glycol monoethyl ether, and methoxymethylbutanol.

Examples of the amide-based solvent include N,N-dimethylformamide, 1-methyl-2-pyrrolidone, 2-pyrrolidinone, 1,3-dimethyl-2-imidazolidinone, 2-pyrrolidinone, F-caprolactam, formamide, N-methylformamide, acetamide, N-methylacetamide, N,N-dimethylacetamide, N-methylpropanamide, and hexamethylphosphoric triamide.

Examples of the ether-based solvent include dioxane, tetrahydrofuran, anisole, and diisobutyl ether. Of these, diisobutyl ether is preferred.

Examples of the hydrocarbon-based solvent include: saturated aliphatic hydrocarbon-based solvents such as pentane, hexane, octane, nonane, decane, undecane, dodecane, hexadecane, 2,2,4-trimethylpentane, and 2,2,3-trimethylhexane; and aromatic hydrocarbon-based solvents such as mesitylene, cumene, pseudocumene, 1,2,4,5-tetramethylbenzene, p-cymene, toluene, xylene, ethylbenzene, propylbenzene, 1-methylpropylbenzene, 2-methylpropylbenzene, dimethylbenzene, diethylbenzene, ethylmethylbenzene, trimethylbenzene, ethyldimethylbenzene, and dipropylbenzene. Of these, saturated aliphatic hydrocarbon-based solvents are preferred, and octane, nonane, decane, undecane, or dodecane is more preferred.

### <Additional Additives>

The metal resist composition may contain additional additives such as a surfactant, water, a dissolution inhibiting compound, a dye, a plasticizer, a photosensitizer, a light-absorbing agent, and a compound that increases solubility in the developer (e.g., a phenol compound having a molecular weight of 1000 or less or an alicyclic or aliphatic compound having a carboxylic acid group).

The surfactant is preferably a fluorine-based surfactant or a silicon-based surfactant. For example, surfactants described in paragraphs [0218] and [0219] of WO2018/193954A can be used.

### [Step 2]

Step 2 is the step of exposing the metal resist film to light. The entire metal resist film may be exposed to light, or the metal resist film may be exposed to light in a pattern.

Preferably, step 2 is the step of exposing the metal resist film to light in a pattern through a photomask.

The photomask is, for example, any well-known photomask. The photomask may be in contact with the metal resist film.

Examples of the light to which the metal resist film is exposed include infrared light, visible light, ultraviolet light, far-ultraviolet light, extreme ultraviolet (EUV) light, X rays, and electron beams.

The wavelength of the exposure light is preferably 250 nm or less, more preferably 220 nm or less, and still more preferably 1 to 200 nm. Specifically, the light is preferably KrF excimer laser light (wavelength: 248 nm), ArF excimer laser light (wavelength: 193 nm), F₂ excimer laser light (wavelength: 157 nm), X rays, EUV light (wavelength: 13 nm), or an electron beam, more preferably KrF excimer laser light, ArF excimer laser light, EUV light, or an electron beam, and still more preferably EUV light or an electron beam.

No particular limitation is imposed on the amount of light exposure so long as the solubility of the metal resist film exposed to light in the developer containing the organic solvent decreases.

The light exposure method may be liquid immersion exposure.

Step 2 may be performed once or two or more times.

### [Step 3]

Step 3 is the step of subjecting the light-exposed metal resist film to developing treatment using a developer. In the developing treatment, unexposed portions of the light-exposed metal resist film are removed, and a pattern is thereby formed.

The developing method used may be any well-known developing method. Specific examples of the developing method include: a method (dipping method) in which the light-exposed metal resist film is immersed in a bath filled with the developer for a prescribed time; a method (puddle method) in which the developer is placed on the surface of the light-exposed metal resist film so as to form a convex puddle due to surface tension and left to stand for a prescribed time to develop the metal resist film; a method (spraying method) in which the developer is sprayed onto the surface of the light-exposed metal resist film; and a method (dynamic dispensing method) in which the developer is continuously dispensed onto a constantly rotating substrate with the light-exposed metal resist film disposed thereon while a nozzle from which the developer is discharged is moved.

After the developing step, the step of terminating the development using a solvent other than the developer may be performed.

The developing time is preferably 10 to 300 seconds and more preferably 20 to 120 seconds.

The temperature of the developer during development is preferably 0 to 50° C. and more preferably 15 to 35° C.

### <Developer>

The chemical solution of the invention can be used as the developer in step 3.

When the pattern forming method does not include step 4 described later or when the pattern forming method includes step 4 described later and the rinsing liquid in step 4 is an additional chemical solution different from the chemical solution, the developer in step 3 is preferably the chemical solution of the invention described above.

When the pattern forming method includes step 4 described later and the rinsing liquid in step 4 is the chemical solution of the invention, the developer in step 3 may be the chemical solution of the invention described above or may be an additional chemical solution different from the chemical solution of the invention.

The additional chemical solution used differs from the chemical solution of the invention described above and can be any well-known developer or any well-known rinsing liquid.

The additional chemical solution contains an organic solvent. Examples of the organic solvent contained in the additional chemical solution include ketone-based solvents, ester-based solvents, alcohol-based solvents, amide-based solvents, ether-based solvents, and hydrocarbon-based solvents. Specific examples include organic solvents that may be contained in the metal resist.

The additional chemical solution may contain one organic solvent alone or may contain a combination of two or more organic solvents.

The additional chemical solution may contain an organic solvent different from those described above, water, a surfactant, etc.

### [Step 4]

Step 4 is the step of washing the pattern obtained in step 3 (developing step) with a rinsing liquid.

Examples of the rinsing method are the same as those of the developing method in step 3 (such as the dipping method, the puddle method, the spraying method, and the dynamic dispensing method).

The treatment time is preferably 10 to 300 seconds and more preferably 10 to 120 seconds.

The temperature of the rinsing liquid is preferably 0 to 50° C. and more preferably 15 to 35° C.

### <Rinsing Liquid>

When the developer in step 3 is the additional chemical solution, it is preferable that the rinsing liquid in step 4 is the chemical solution of the invention described above. When the developer in step 3 is the chemical solution of the invention described above, the rinsing liquid in step 4 may be the chemical solution of the invention described above or may be the additional chemical solution.

Examples of the additional chemical solution that can be used as the rinsing liquid are the same as those of the chemical solution that can be used as the developer, and preferred forms of the additional chemical solution are also the same as those of the chemical solution that can be used as the developer.

### [Additional Steps]

The pattern forming method may further include additional steps other than steps 1 to 4.

Examples of the additional steps include a post-exposure baking step, a post-baking step, an etching step, and a purification step.

### <Post-Exposure Baking Step>

Preferably, the pattern forming method includes, after step 2 (the light exposure step) but before step 3 (the developing step), a post-exposure baking (PEB) step.

The heating temperature for the post-exposure baking is preferably 80 to 200° C., more preferably 80 to 180° C., and still more preferably 80 to 150° C. The heating time is preferably 10 to 1000 seconds, more preferably 10 to 180 seconds, and still more preferably 30 to 120 seconds.

The post-exposure baking may be performed using means included with a well-known exposing device and/or a well-known developing device and a hot plate. The post-exposure baking may be performed once or two or more times.

### <Post-Baking Step>

Preferably, the pattern forming method includes, after step 4 (the rinsing step), the step of heating the pattern (the post-baking step). With the post-baking (PB) step, the developer and the rinsing liquid remaining between traces of the pattern and inside the pattern can be removed, and the surface roughness of the pattern can be improved.

The heating temperature in the post-baking step is preferably 40 to 250° C. and more preferably 80 to 200° C.

The heating time in the post-baking step is preferably 10 to 180 seconds and more preferably 30 to 120 seconds.

### <Etching Step>

The pattern forming method may include the etching step of etching the substrate using the formed pattern as a mask.

The etching method used may be any well-known etching method. Specific examples include a method described in Proceedings of Society of Photo-Optical Instrumentation Engineers (Proc. Of SPIE) Vol. 6924, 692420 (2008), a method described in “Chapter 4 Etching” in “Semiconductor Process Text Book, 4th Ed., published in 2007, publisher: SEMI Japan,” and a method described in JP2009-267112A.

### <Purification Step>

The pattern forming method may include the purification step of purifying the metal resist composition, the developer, the rinsing liquid, and/or other various components (such as the composition for forming the undercoat film and the composition for forming the topcoat) used for the pattern forming method.

The purification method is, for example, a well-known purification method and is preferably filtering or a method using an adsorbent.

### [Method for Producing Electronic Device]

The chemical solution of the invention can be used for a method for producing an electronic device. A preferred form of the invention is an electronic device production method including the step of forming a pattern using the chemical solution of the invention according to the pattern forming method described above.

The electronic device is suitably installed in electric and electronic devices (such as household electrical appliances, OA (Office Automation) devices, media-related devices, optical devices, and communication devices).

### EXAMPLES

The present invention will be further described in detail by way of Examples.

Materials, amounts used, ratios, treatment details, treatment procedures, etc. shown in the following Examples can be appropriately changed so long as they do not depart from the gist of the invention. Therefore, the scope of the present invention should not be construed as limited to the following Examples.

### [Preparation of Chemical Solutions]

### [Preparation of Raw Materials]

PGMEA, PGME, and organic acids were synthesized and/or purified according to the following procedures.

### <Synthesis and Purification of PGME>

An unpurified product containing PGME was synthesized using a method described in JP2011-509998A.

Next, the obtained unpurified product was subjected to circulating filtration purification using a filtration device including the following ion exchange resin and filters connected in series from the upstream side and further including a return passage extending from the most downstream side to the most upstream side. The number of circulation cycles was 50.

The details of the members in the filtration device are shown below in the order from the upstream side.
Anion exchange resin (an anion exchange resin described in Production Example 1 in JP2009-155208A)
Ion exchange filter (IonKleen SL manufactured by Pall Corporation)
Nylon filter (Asymmetric manufactured by Pall Corporation, pore size: 5 nm)
UPE filter (Purasol SP/SN solvent purifier manufactured by Entegris)
PTFE filter (XpressKLEEN manufactured by Pall Corporation, pore size: 3 nm)
UPE filter (Microgard manufactured by Entegris, pore size: 3 nm)

In the circulating filtration purification, the operation in which the unpurified product is caused to pass from the most upstream purification member to the most downstream purification member is counted as one circulation cycle.

A distillation column in which a first plate distillation column (the theoretical number of plates: 150) including no pressure reduction mechanism and a second plate distillation column (the theoretical number of plates: 150) including a pressure reduction mechanism were connected in series was used to perform distillation purification sequentially from the first plate distillation column to thereby obtain PGME used as a raw material of chemical solutions.

### <Purification of Organic Acids>

A filtration device including the following filters connected in series from the upstream side and further including a return passage extending from the most downstream side to the most upstream side was used to subject acetic acid (manufactured by KANTO CHEMICAL Co., Inc.) to circulating filtration purification. The number of circulation cycles was 50.

The details of the members in the filtration device are shown below in the order from the upstream side.
Ion exchange filter (IonKleen SL manufactured by Pall Corporation)
Nylon filter (Asymmetric manufactured by Pall Corporation, pore size: 5 nm)
UPE filter (Purasol SP/SN solvent purifier manufactured by Entegris)
PTFE filter (XpressKLEEN manufactured by Pall Corporation, pore size: 3 nm)
UPE filter (Microgard manufactured by Entegris, pore size: 3 nm)

Then distillation purification was performed using the same method as that for the distillation purification of PGME, and acetic acid used as a raw material of the chemical solutions was thereby obtained.

Formic acid (manufactured by KANTO CHEMICAL Co., Inc.), propionic acid (manufactured by Sigma-Aldrich), butyric acid (manufactured by Sigma-Aldrich), glycolic acid (manufactured by Wako Pure Chemical Industries, Ltd.), and lactic acid (manufactured by Sigma-Aldrich) were purified using the same purification method as that for acetic acid including circulating filtration purification and distillation purification, and organic acids used as raw materials of the chemical solutions were thereby obtained.

### <PGMEA>

The PGME synthesized and circulating-filtration-purified by the method described above and the acetic acid circulating-filtration-purified by the method described above were used as raw materials to synthesize an unpurified product containing PGMEA by ester synthesis.

The ester synthesis was performed using a method described in JP2001-521918A.

The obtained unpurified product containing PGMEA was subjected to dewatering treatment by a column method using a molecular sieve 3A (manufactured by FUJIFILM Wako Pure Chemical Corporation).

Next, the resulting unpurified product containing PGMEA was subjected to distillation purification using the same method as that for the distillation purification of PGME.

A filtration device including the following filters connected in series from the upstream side and further including a return passage extending from the most downstream side to the most upstream side was used to subject the unpurified product containing PGMEA to circulating filtration purification, and PGMEA used as a raw material of the chemical solutions was thereby obtained. The number of circulation cycles was 50.

The details of the members in the filtration device are shown below in the order from the upstream side.
Nylon filter (Asymmetric manufactured by Pall Corporation, pore size: 5 nm)
UPE filter (Purasol SP/SN solvent purifier manufactured by Entegris)
PTFE filter (XpressKLEEN manufactured by Pall Corporation, pore size: 3 nm)
UPE filter (Microgard manufactured by Entegris, pore size: 3 nm)

In the manner described above, PGMEA, PGME, and the organic acids were obtained in which the water content was reduced to the detection limit or lower and the boron atom content and the Pb atom content were less than 0.0001 ppt by mass.

The water content was measured using the above-described Karl Fischer moisture meter (product name: “MKC-710M” manufactured by Kyoto Electronics Manufacturing Co., Ltd., Karl Fischer coulometric titration type). The limit of detection of the water content by this device was 1 ppm by mass.

The content of boron atoms and the content of Pb atoms in the PGMEA obtained by the procedure described above were checked.

The content of boron atoms was measured using the above-described ICP-MS (device used: Agilent 8900 triple quadrupole ICP-MS (manufactured by Agilent Technologies, semiconductor analysis use, option: #200)). The limit of detection of boron atoms by this device was 0.6 ppt by mass (unconcentrated).

The content of Pb atoms was measured using the above-described ICP-MS (device used: Agilent 8900 triple quadrupole ICP-MS (manufactured by Agilent Technologies, semiconductor analysis use, option: #200)). The limit of detection of Pb atoms by this device was 0.1 ppt by mass (unconcentrated).

The PGMEA, PGME, and organic acids were concentrated in the same manner as in the measurement method for the chemical solution described later, and then the boron atom content and the Pb content in each of the PGMEA, PGME, and organic acids were measured using the device described above. The boron atom content was found to be 0.0001 ppt by mass or less, and the Pb content was found to be 0.0001 ppt by mass or less.

For each of the above-obtained PGMEA, PGME, and organic acids concentrated in the same manner as in the measurement method for the chemical solution described later and then used for the measurement of Pb atoms using the device described above, the contents of transition elements other than Pb atoms and measurable by ICP-MS were all less than 0.0001 ppt by mass.

### [Preparation of Liquids]

The PGME purified by the method described above, one of the organic acids purified by the method described above, ultrapure water, a boron atom source, and a Pb atom source were added to the PGMEA purified by the method described above such that a composition shown in one of the following tables was obtained, and a chemical solution in one of Examples and Comparative Examples was thereby prepared.

The boron atom source was added by the following method. Solid high-purity boron (manufactured by Tokuyama Corporation) was immersed in a chemical solution for a prescribed time to allow boron to dissolve in the chemical solution such that the boron atom content was adjusted to a prescribed value.

The amount of high-purity boron immersed in the chemical solution and the immersion time were set as follows. A calibration curve for the dissolution amount of boron atoms in relation to the surface area of the high-purity boron and the immersion time was produced, and the amount of immersed high-purity boron and the immersion time were set such that the final boron atom content in the chemical solution was adjusted to a prescribed value. The boron atom content in each chemical solution was measured by ICP-MS using an Agilent 8900 triple quadrupole ICP-MS (manufactured by Agilent Technologies, semiconductor analysis use, option: #200).

When the content of boron atoms in a chemical solution was quantified, the following procedure was used.

First, ultrapure water (standard product) was added to the chemical solution to be subjected to quantification of boron atoms in an amount of 0.001% by mass based on the mass of the chemical solution. In the ultrapure water added, the boron atom content was 0.0001 ppt by mass. To determine the boron atom content in the ultrapure water, the ultrapure water was concentrated by a factor of 10000, and then the measurement was performed using the same method as described above. As described above, it is expected from the potential-pH diagram for the water-boron system that boron is present in the form of boric acid in the ultrapure water.

Next, the chemical solution with the ultrapure water added thereto was heated at 100° C. for 1 hour under reflux conditions to convert boron present in the chemical solution to the form of boric acid. Then the organic solvents and water contained in the chemical solution were removed at 160 to 180° C. to concentrate the non-volatile components contained in the chemical solution, and the boron atom content was quantified using the device described above. The content of boron atoms contained in the chemical solution was computed in consideration of the mass of boron contained in the ultrapure water.

When the non-volatile components were concentrated, the contents of boron atoms in different chemical solutions with concentration factors ranging from 10 to 1000 were computed. Then positive correlation was found between the concentration factor and the boron atom content, and the coefficient of determination (R²) in linear regression was more than 0.98. Specifically, when a chemical solution is concentrated using the method described above, the content of boron atoms contained in the chemical solution can be quantified.

To add the Pb atom source, a PGMEA solution of Pb nanoparticles ((5N) 99.999% Lead Oxide Nanopowder manufactured by American Elements) with the concentration adjusted to a prescribe value was added to the chemical solution.

### [Preparation of Metal Resist Composition]

Monobutyltin oxide hydrate (BuSnOOH) powder (0.209 g, TCI America) was added to 4-methyl-2-pentanol (10 mL) to prepare a metal resist precursor solution. The solution was placed in a closed vial and stirred for 24 hours. The resulting mixture was subjected to centrifugation at 4000 rpm for 15 minutes and filtrated using a 0.45 μm PTFE syringe filter to remove insoluble materials, and a metal resist composition was thereby obtained.

The organic solvent in the metal resist composition was removed, and the resulting metal resist composition was fired at 600° C. The content of Sn in the metal resist composition determined from the remaining mass of SnO₂ was 0.093M.

The metal resist precursor solution was subjected to DLS (Dynamic Light Scattering) analysis using a Moebius device (manufactured by Wyatt Technology). The results were consistent with a unimodal distribution of particles having an average particle diameter of 2 nm and also consistent with the reported diameter of dodecameric butyltin hydroxide oxide polyatomic cations (Eychenne-Baron et al., Organometallics, 19, 1940-1949 (2000)).

### [Evaluation]

[Ability to Suppress Occurrence of Defects Originating from Specific Elements]

A silicon substrate with a diameter of 300 mm was prepared, and a surface defect inspection system (SurfScan SP7 manufactured by KLA) was used to irradiate the surface of the silicon substrate with laser light, and the scattered light was measured to determine the positions of defects on the silicon substrate and their sizes.

One of the chemical solutions in the Examples and Comparative Examples was applied to the silicon substrate using a coater/developer (CLEAN TRACK LITHIUS PRO Z manufactured by Tokyo Electron Ltd.). Then the silicon substrate with the coating film formed thereon was spin-dried at 2000 rpm for 30 seconds, and the surface defect inspection system (SurfScan SP7 manufactured by KLA) was used to determine the positions of defects on the silicon substrate and their sizes using the method described above.

Defects originating from the chemical solution were extracted based on the positions of defects, the numbers of defects, and the sizes of the defects before and after the application of the chemical solution. The extracted defects originating from the chemical solution were subjected to qualitative elemental analysis using a defect review system (SEMVision G7E manufactured by Applied Materials).

The qualitative elemental analysis was performed using an SEM-EDS (Scanning Electron Microscope-Energy Dispersive X-ray Spectroscopy) installed in the defect review system.

The number of defects containing the specific elements (these defects are hereinafter referred to as “specific element-containing defects”) was computed from the EDS spectrum obtained by the qualitative elemental analysis, and the computation results were used to evaluate the ability to suppress the occurrence of defects originating from the specific elements according to the following evaluation criteria.

The smaller the number of specific element-containing defects, the better.

<Criteria for Evaluation of Ability to Suppress Occurrence of Defects Originating from Specific Elements>
A: The number of specific element-containing defects is 1 or less.
B: The number of specific element-containing defects is more than 1 and 3 or less.
C: The number of specific element-containing defects is more than 3 and 5 or less.
D: The number of specific element-containing defects is more than 5.
   [Ability to Suppress Occurrence of Defects Originating from Boron Atoms]

The number of defects containing elemental boron (boron-containing defects) was computed according to the evaluation procedure described above in the [Ability to suppress occurrence of defects originating from specific elements] section, and the computation results were used to evaluate the ability to suppress the occurrence of defects originating from boron atoms according to the following evaluation criteria.

The smaller the number of boron-containing defects, the better.

<Criteria for Evaluation of Ability to Suppress Occurrence of Defects Originating from Boron Atoms>
A: The number of boron-containing defects is 1 or less.
B: The number of boron-containing defects is more than 1 and 3 or less.
C: The number of boron-containing defects is more than 3 and 5 or less.
D: The number of boron-containing defects is more than 5.

### [Pattern Resolution]

An undercoat film-forming composition SHB-A940 (manufactured by Shin-Etsu Chemical Co., Ltd.) was applied to a silicon wafer having a diameter of 300 mm and baked at 205° C. for 60 seconds to form an undercoat film having a thickness of 20 nm. The metal resist composition was applied to the obtained undercoat film and baked at 100° C. for 90 seconds to form a metal resist film having a thickness of 22 nm. The silicon wafer having the metal resist film was thereby formed.

The silicon water having the metal resist film was subjected to pattern light exposure using an EUV scanner NXE3400 (manufactured by ASML, NA: 0.33) at a minimum light exposure at a resolution limit described later. The reticle used was a pillar pattern with a pitch of 45 nm and an opening size of 25 nm. Then post-exposure baking (PEB) was performed at 150° C. for 90 seconds.

Next, in Examples 1 to 32 and Comparative Examples 1 to 4, the chemical solution in one of the Examples and Comparative Examples was used to perform puddle development treatment for 30 seconds, and then the wafter was rotated at 4000 rpm for 30 seconds to dry the wafter. A pillar pattern with a pitch of 45 nm was thereby obtained.

In Examples 101 to 132 and Comparative Examples 101 to 104, the chemical solution in Comparative Example 3 was used to perform puddle development treatment for 30 seconds. Next, while the wafer was rotated at 1000 rpm, one of the chemical solutions in the Examples and Comparative Examples was poured for 10 seconds to perform rinsing treatment. Then the wafer was rotated at 4000 rpm for 30 seconds to dry the wafer, and a pillar pattern with a pitch of 45 nm was thereby obtained.

A critical dimension scanning electron microscope (CG6300 manufactured by Hitachi High-Tech Corporation) was used to observe 2000 pillars for each of different light exposure amounts, and the average pillar diameters and the quality of the patterns were checked. The average pillar diameter at the minimum light exposure amount at which the number of collapsed pillars among the 2000 observed pillars was zero was defined as a critical resolution, and the resolution was evaluated according to the following evaluation criteria.

The smaller the critical resolution, the higher the resolution, and the better.
A: The critical resolution is 14 nm or less.
B: The critical resolution is more than 14 nm and 15 nm or less.
C: The critical resolution is more than 15 nm and 16 nm or less.
D: The critical resolution is more than 16 nm.
   [Pattern Resolution after Storage]

Chemical solutions stored at room temperature (22° C.) for one month were used to compute the critical resolutions using the same method as that for the evaluation of the [Pattern resolution] described above.

The critical resolutions before and after storage were compared, and the resistance to deterioration of the resolution of each chemical solution due to storage was evaluated according to the following evaluation criteria.

The smaller the increase in the critical resolution before and after storage, the smaller the degree of deterioration of the pattern resolution of the chemical solution during storage, and the better.
A: The increase in the critical resolution is 0.3 nm or less.
B: The increase in the critical resolution is more than 0.3 nm and 1 nm or less.
C: The increase in the critical resolution is more than 1 nm and 2 nm or less.
D: The increase in the critical resolution is more than 2 nm and 3 nm or less.
E: The increase in the critical resolution is more than 3 nm.

### [Results]

The compositions of the chemical solutions in the Examples and Comparative Examples and the evaluation results are shown in Tables 1 and 2.

In each table, “Balance” in the “PGMEA” column means that the remaining portion other than the organic acid, alcohol, water, boron, and Pb in the table is PGMEA.

In each table, the “Boron [ppt]” column indicates the content of boron atoms (unit: ppt by mass) based on the total mass of the chemical solution, and the “Pb [ppt]” column indicates the content of Pb atoms (unit: ppt by mass) based on the total mass of the chemical solution.

In each table, the “Application of chemical solution” column indicates whether the chemical solution was used as a developer or a rinsing liquid.

In each table, the “Pattern resolution” column indicates the results of evaluation of the [Pattern Resolution] described above, and the “Pattern resolution after storage” indicates the results of evaluation of the [Pattern resolution after storage].

TABLE 1

| | Composition of chemical solution | | | | | | | |
|---|---|---|---|---|---|---|---|---|
| | | Organic acid | | Alcohol | | | | |
| Table 1 | PGMEA | | Content | | Content | Water | Boron | Pb |
| (1) | content | Type | [% by mass] | Type | [% by mass] | [% by mass] | [ppt] | [ppt] |
| Example 1 | Balance | Acetic acid | 15.0 | PGME | 0.01 | 0.003 | 0.5 | 5 |
| Example 2 | Balance | Acetic acid | 15.0 | PGME | 0.01 | 0.003 | 15 | 5 |
| Example 3 | Balance | Acetic acid | 15.0 | PGME | 0.01 | 0.003 | 56 | 5 |
| Example 4 | Balance | Acetic acid | 15.0 | PGME | 0.01 | 0.003 | 85 | 5 |
| Example 5 | Balance | Acetic acid | 15.0 | PGME | 0.01 | 0.003 | 0.0026 | 5 |
| Example 6 | Balance | Acetic acid | 15.0 | PGME | 0.01 | 0.003 | 0.028 | 5 |
| Example 7 | Balance | Acetic acid | 15.0 | PGME | 0.01 | 0.003 | 0.37 | 5 |
| Example 8 | Balance | Acetic acid | 19.8 | PGME | 0.01 | 0.003 | 0.5 | 5 |
| Example 9 | Balance | Acetic acid | 26.3 | PGME | 0.01 | 0.003 | 0.5 | 5 |
| Example 10 | Balance | Acetic acid | 33.1 | PGME | 0.01 | 0.003 | 0.5 | 5 |
| Example 11 | Balance | Acetic acid | 38.9 | PGME | 0.01 | 0.003 | 0.5 | 5 |
| Example 12 | Balance | Acetic acid | 1.1 | PGME | 0.01 | 0.003 | 0.5 | 5 |
| Example 13 | Balance | Acetic acid | 2.6 | PGME | 0.01 | 0.003 | 0.5 | 5 |
| Example 14 | Balance | Acetic acid | 5.4 | PGME | 0.01 | 0.003 | 0.5 | 5 |
| Example 15 | Balance | Acetic acid | 15.0 | PGME | 0.01 | 0.006 | 0.5 | 5 |
| Example 16 | Balance | Acetic acid | 15.0 | PGME | 0.01 | 0.009 | 0.5 | 5 |
| Example 17 | Balance | Acetic acid | 15.0 | PGME | 0.01 | 0.012 | 0.5 | 5 |
| Example 18 | Balance | Acetic acid | 15.0 | PGME | 0.01 | 0.00008 | 0.5 | 5 |
| Example 19 | Balance | Acetic acid | 15.0 | PGME | 0.01 | 0.00012 | 0.5 | 5 |
| Example 20 | Balance | Acetic acid | 15.0 | PGME | 0.01 | 0.0005 | 0.5 | 5 |

| | | Evaluation | | | |
|---|---|---|---|---|---|
| | | Ability to suppress | Ability to suppress | | Pattern |
| | Application | occurrence of defects | occurrence of defects | | resolution |
| Table 1 | of chemical | originating from | originating from | Pattern | after |
| (1) | solution | boron | specific elements | resolution | storage |
| Example 1 | Developer | A | A | A | A |
| Example 2 | Developer | A | A | A | A |
| Example 3 | Developer | B | A | B | A |
| Example 4 | Developer | C | A | B | A |
| Example 5 | Developer | A | C | A | A |
| Example 6 | Developer | A | B | A | A |
| Example 7 | Developer | A | A | A | A |
| Example 8 | Developer | A | A | A | B |
| Example 9 | Developer | A | A | B | B |
| Example 10 | Developer | A | A | C | C |
| Example 11 | Developer | A | A | C | D |
| Example 12 | Developer | A | A | C | A |
| Example 13 | Developer | A | A | B | A |
| Example 14 | Developer | A | A | A | A |
| Example 15 | Developer | A | A | A | A |
| Example 16 | Developer | A | A | A | B |
| Example 17 | Developer | A | A | A | C |
| Example 18 | Developer | A | A | A | A |
| Example 19 | Developer | A | A | A | A |
| Example 20 | Developer | A | A | A | A |

TABLE 2

| | Composition of chemical solution | | | | | | | |
|---|---|---|---|---|---|---|---|---|
| | | Organic acid | | Alcohol | | | | |
| Table 1 | PGMEA | | Content | | Content | Water | Boron | Pb |
| (2) | content | Type | [% by mass] | Type | [% by mass] | [% by mass] | [ppt] | [ppt] |
| Example 21 | Balance | Acetic acid | 15.0 | PGME | 0.01 | 0.003 | 0.5 | 0.0008 |
| Example 22 | Balance | Acetic acid | 15.0 | PGME | 0.01 | 0.003 | 0.5 | 0.005 |
| Example 23 | Balance | Acetic acid | 15.0 | PGME | 0.01 | 0.003 | 0.5 | 0.01 |
| Example 24 | Balance | Acetic acid | 15.0 | PGME | 0.01 | 0.003 | 0.5 | 1 |
| Example 25 | Balance | Acetic acid | 15.0 | PGME | 0.01 | 0.003 | 0.5 | 3 |
| Example 26 | Balance | Acetic acid | 15.0 | PGME | 0.01 | 0.003 | 0.5 | 12 |
| Example 27 | Balance | Acetic acid | 15.0 | PGME | 0.01 | 0.003 | 0.5 | 141 |
| Example 28 | Balance | Formic acid | 15.0 | PGME | 0.01 | 0.003 | 0.5 | 5 |
| Example 29 | Balance | Propionic acid | 15.0 | PGME | 0.01 | 0.003 | 0.5 | 5 |
| Example 30 | Balance | Butyric acid | 15.0 | PGME | 0.01 | 0.003 | 0.5 | 5 |
| Example 31 | Balance | Glycolic acid | 15.0 | PGME | 0.01 | 0.003 | 0.5 | 5 |
| Example 32 | Balance | Lactic acid | 15.0 | PGME | 0.01 | 0.003 | 0.5 | 5 |
| Comparative | Balance | Acetic acid | 15.0 | PGME | 0.01 | 0.003 | 102 | 5 |
| Example 1 | | | | | | | | |
| Comparative | Balance | Acetic acid | 15.0 | PGME | 0.01 | 0.003 | 0.0008 | 5 |
| Example 2 | | | | | | | | |
| Comparative | Balance | Acetic acid | 43.3 | PGME | 0.01 | 0.003 | 0.5 | 5 |
| Example 3 | | | | | | | | |
| Comparative | Balance | Acetic acid | 0.7 | PGME | 0.01 | 0.003 | 0.5 | 5 |
| Example 4 | | | | | | | | |

| | | Evaluation | | | |
|---|---|---|---|---|---|
| | | Ability to suppress | Ability to suppress | | Pattern |
| | Application | occurrence of defects | occurrence of defects | | resolution |
| Table 1 | of chemical | originating from | originating from | Pattern | after |
| (2) | solution | boron | specific elements | resolution | storage |
| Example 21 | Developer | A | A | A | A |
| Example 22 | Developer | A | A | A | A |
| Example 23 | Developer | A | A | A | A |
| Example 24 | Developer | A | A | A | A |
| Example 25 | Developer | A | A | A | A |
| Example 26 | Developer | A | A | A | A |
| Example 27 | Developer | A | A | A | A |
| Example 28 | Developer | A | A | A | A |
| Example 29 | Developer | A | A | A | A |
| Example 30 | Developer | A | A | A | A |
| Example 31 | Developer | A | A | A | A |
| Example 32 | Developer | A | A | A | A |
| Comparative | Developer | D | A | D | A |
| Example 1 | | | | | |
| Comparative | Developer | A | D | A | A |
| Example 2 | | | | | |
| Comparative | Developer | A | A | D | E |
| Example 3 | | | | | |
| Comparative | Developer | A | A | D | A |
| Example 4 | | | | | |

TABLE 3

| | Composition of chemical solution | | | | | | | |
|---|---|---|---|---|---|---|---|---|
| | | Organic acid | | Alcohol | | | | |
| Table 2 | PGMEA | | Content | | Content | Water | Boron | Pb |
| (1) | content | Type | [% by mass] | Type | [% by mass] | [% by mass] | [ppt] | [ppt] |
| Example 101 | Balance | Acetic acid | 15.0 | PGME | 0.01 | 0.003 | 0.5 | 5 |
| Example 102 | Balance | Acetic acid | 15.0 | PGME | 0.01 | 0.003 | 15 | 5 |
| Example 103 | Balance | Acetic acid | 15.0 | PGME | 0.01 | 0.003 | 56 | 5 |
| Example 104 | Balance | Acetic acid | 15.0 | PGME | 0.01 | 0.003 | 85 | 5 |
| Example 105 | Balance | Acetic acid | 15.0 | PGME | 0.01 | 0.003 | 0.0026 | 5 |
| Example 106 | Balance | Acetic acid | 15.0 | PGME | 0.01 | 0.003 | 0.028 | 5 |
| Example 107 | Balance | Acetic acid | 15.0 | PGME | 0.01 | 0.003 | 0.37 | 5 |
| Example 108 | Balance | Acetic acid | 19.8 | PGME | 0.01 | 0.003 | 0.5 | 5 |
| Example 109 | Balance | Acetic acid | 26.3 | PGME | 0.01 | 0.003 | 0.5 | 5 |
| Example 110 | Balance | Acetic acid | 33.1 | PGME | 0.01 | 0.003 | 0.5 | 5 |
| Example 111 | Balance | Acetic acid | 38.9 | PGME | 0.01 | 0.003 | 0.5 | 5 |
| Example 112 | Balance | Acetic acid | 1.1 | PGME | 0.01 | 0.003 | 0.5 | 5 |
| Example 113 | Balance | Acetic acid | 2.6 | PGME | 0.01 | 0.003 | 0.5 | 5 |
| Example 114 | Balance | Acetic acid | 5.4 | PGME | 0.01 | 0.003 | 0.5 | 5 |
| Example 115 | Balance | Acetic acid | 15.0 | PGME | 0.01 | 0.006 | 0.5 | 5 |
| Example 116 | Balance | Acetic acid | 15.0 | PGME | 0.01 | 0.009 | 0.5 | 5 |
| Example 117 | Balance | Acetic acid | 15.0 | PGME | 0.01 | 0.012 | 0.5 | 5 |
| Example 118 | Balance | Acetic acid | 15.0 | PGME | 0.01 | 0.00008 | 0.5 | 5 |
| Example 119 | Balance | Acetic acid | 15.0 | PGME | 0.01 | 0.00012 | 0.5 | 5 |
| Example 120 | Balance | Acetic acid | 15.0 | PGME | 0.01 | 0.0005 | 0.5 | 5 |

| | | Evaluation | | | |
|---|---|---|---|---|---|
| | | Ability to suppress | Ability to suppress | | Pattern |
| | Application | occurrence of defects | occurrence of defects | | resolution |
| Table 2 | of chemical | originating from | originating from | Pattern | after |
| (1) | solution | boron | specific elements | resolution | storage |
| Example 101 | Rinsing liquid | A | A | A | A |
| Example 102 | Rinsing liquid | B | A | A | A |
| Example 103 | Rinsing liquid | C | A | B | A |
| Example 104 | Rinsing liquid | D | A | B | A |
| Example 105 | Rinsing liquid | A | D | A | A |
| Example 106 | Rinsing liquid | A | C | A | A |
| Example 107 | Rinsing liquid | A | B | A | A |
| Example 108 | Rinsing liquid | A | A | A | B |
| Example 109 | Rinsing liquid | A | A | B | B |
| Example 110 | Rinsing liquid | A | A | C | C |
| Example 111 | Rinsing liquid | A | A | C | D |
| Example 112 | Rinsing liquid | A | A | C | A |
| Example 113 | Rinsing liquid | A | A | B | A |
| Example 114 | Rinsing liquid | A | A | A | A |
| Example 115 | Rinsing liquid | A | A | A | A |
| Example 116 | Rinsing liquid | A | A | A | B |
| Example 117 | Rinsing liquid | A | A | A | C |
| Example 118 | Rinsing liquid | A | A | A | A |
| Example 119 | Rinsing liquid | A | A | A | A |
| Example 120 | Rinsing liquid | A | A | A | A |

TABLE 4

| | Composition of chemical solution | | | | | | | |
|---|---|---|---|---|---|---|---|---|
| | | Organic acid | | Alcohol | | | | |
| Table 2 | PGMEA | | Content | | Content | Water | Boron | Pb |
| (2) | content | Type | [% by mass] | Type | [% by mass] | [% by mass] | [ppt] | [ppt] |
| Example 121 | Balance | Acetic acid | 15.0 | PGME | 0.01 | 0.003 | 0.5 | 0.0008 |
| Example 122 | Balance | Acetic acid | 15.0 | PGME | 0.01 | 0.003 | 0.5 | 0.005 |
| Example 123 | Balance | Acetic acid | 15.0 | PGME | 0.01 | 0.003 | 0.5 | 0.01 |
| Example 124 | Balance | Acetic acid | 15.0 | PGME | 0.01 | 0.003 | 0.5 | 1 |
| Example 125 | Balance | Acetic acid | 15.0 | PGME | 0.01 | 0.003 | 0.5 | 3 |
| Example 126 | Balance | Acetic acid | 15.0 | PGME | 0.01 | 0.003 | 0.5 | 12 |
| Example 127 | Balance | Acetic acid | 15.0 | PGME | 0.01 | 0.003 | 0.5 | 141 |
| Example 128 | Balance | Formic acid | 15.0 | PGME | 0.01 | 0.003 | 0.5 | 5 |
| Example 129 | Balance | Propionic acid | 15.0 | PGME | 0.01 | 0.003 | 0.5 | 5 |
| Example 130 | Balance | Butyric acid | 15.0 | PGME | 0.01 | 0.003 | 0.5 | 5 |
| Example 131 | Balance | Glycolic acid | 15.0 | PGME | 0.01 | 0.003 | 0.5 | 5 |
| Example 132 | Balance | Lactic acid | 15.0 | PGME | 0.01 | 0.003 | 0.5 | 5 |
| Comparative | Balance | Acetic acid | 15.0 | PGME | 0.01 | 0.003 | 102 | 5 |
| Example 101 | | | | | | | | |
| Comparative | Balance | Acetic acid | 15.0 | PGME | 0.01 | 0.003 | 0.0008 | 5 |
| Example 102 | | | | | | | | |
| Comparative | Balance | Acetic acid | 43.3 | PGME | 0.01 | 0.003 | 0.5 | 5 |
| Example 103 | | | | | | | | |
| Comparative | Balance | Acetic acid | 0.7 | PGME | 0.01 | 0.003 | 0.5 | 5 |
| Example 104 | | | | | | | | |

| | | Evaluation | | | |
|---|---|---|---|---|---|
| | | Ability to suppress | Ability to suppress | | Pattern |
| | Application | occurrence of defects | occurrence of defects | | resolution |
| Table 2 | of chemical | originating from | originating from | Pattern | after |
| (2) | solution | boron | specific elements | resolution | storage |
| Example 121 | Rinsing liquid | A | A | A | A |
| Example 122 | Rinsing liquid | A | A | A | A |
| Example 123 | Rinsing liquid | A | A | A | A |
| Example 124 | Rinsing liquid | A | A | A | A |
| Example 125 | Rinsing liquid | A | A | A | A |
| Example 126 | Rinsing liquid | A | A | A | A |
| Example 127 | Rinsing liquid | A | A | A | A |
| Example 128 | Rinsing liquid | A | A | A | A |
| Example 129 | Rinsing liquid | A | A | A | A |
| Example 130 | Rinsing liquid | A | A | A | A |
| Example 131 | Rinsing liquid | A | A | A | A |
| Example 132 | Rinsing liquid | A | A | A | A |
| Comparative | Rinsing liquid | E | A | D | A |
| Example 101 | | | | | |
| Comparative | Rinsing liquid | A | E | A | A |
| Example 102 | | | | | |
| Comparative | Rinsing liquid | A | A | D | E |
| Example 103 | | | | | |
| Comparative | Rinsing liquid | A | A | D | A |
| Example 104 | | | | | |

As can be seen from the results in Tables 1 and 2, in the chemical solutions of the invention produced in Examples 1 to 32 and Examples 101 to 132, the effects of the invention are higher than those in Comparative Examples 1 and 101 in which the content of boron atoms is more than 100 ppt by mass, in Comparative Examples 2 and 102 in which the content of boron atoms is less than 0.001 ppt by mass, in Comparative Examples 3 and 103 in which the content of the organic acid is more than 40% by mass, and in Comparative Examples 4 and 104 in which the content of the organic acid is less than 1% by mass.

As can be seen from comparisons among Examples 1 to 4 and among Examples 101 to 104, when the content of boron atoms is 75 ppt by mass or less based on the total mass of the chemical solution, the occurrence of defects originating from boron atoms can be further reduced. When the content of boron atoms is 50 ppt by mass or less, the occurrence of defects originating from boron atoms can be still further reduced, and the pattern resolution is higher.

As can be seen from comparison among Examples 1 and 5 to 7 and among Examples 101 and 105 to 107, when the content of boron atoms is 0.01 ppt by mass or more based on the total mass of the chemical solution, the occurrence of defects originating from the specific elements can be further reduced. When the content of boron atoms is 0.05 ppt by mass or more, the occurrence of defects originating from the specific elements can be still further reduced.

As can be seen from comparisons among Examples 1 and 8 to 11 and among Examples 101 and 108 to 111, when the content of the organic acid is 30% by mass or less based on the total mass of the chemical solution, the pattern resolution and the pattern resolution after storage are higher. When the content of the organic acid is 25% by mass or less, the pattern resolution is still higher.

As can be seen from comparisons among Examples 1 and 12 to 14 and among Examples 101 and 112 to 114, when the content of the organic acid is 2% by mass or more based on the total mass of the chemical solution, the pattern resolution is higher. When the content of the organic acid is 3% by mass or more, the pattern resolution is still higher.

What is claimed is:

1. A chemical solution comprising: propylene glycol monomethyl ether acetate; and an organic acid,
wherein a content of the organic acid is 1% by mass or more and less than 40% by mass based on a total mass of the chemical solution, and
wherein a content of boron atoms is 0.001 to 100 ppt by mass based on the total mass of the chemical solution.

2. The chemical solution according to claim 1, wherein a total content of the propylene glycol monomethyl ether acetate and the organic acid is 98% by mass or more based on the total mass of the chemical solution.

3. The chemical solution according to claim 1, wherein a total content of the propylene glycol monomethyl ether acetate and the organic acid is 99.5% by mass or more based on the total mass of the chemical solution.

4. The chemical solution according to claim 1, wherein the organic acid includes at least one selected from the group consisting of formic acid, acetic acid, propionic acid, butyric acid, glycolic acid, and lactic acid.

5. The chemical solution according to claim 1, further comprising Pb atoms,
wherein a content of the Pb atoms is 0.001 to 10 ppt by mass based on the total mass of the chemical solution.

6. The chemical solution according to claim 1, further comprising water,
wherein a content of the water is 0.0001 to 0.01% by mass based on the total mass of the chemical solution.

7. The chemical solution according to claim 1, wherein the content of the boron atoms is 0.05 to 50 ppt by mass based on the total mass of the chemical solution.

8. The chemical solution according to claim 1, wherein the content of the organic acid is 2 to 30% by mass based on the total mass of the chemical solution.

9. The chemical solution according to claim 1, wherein the chemical solution is used as a developer or a rinsing liquid.

10. A chemical solution-housing article comprising: a container; and the chemical solution according to claim 1, the chemical solution being housed in the container.

11. The chemical solution-housing article according to claim 10, wherein the container has a liquid-contacting portion that is in contact with the chemical solution and that is formed of a nonmetallic material or stainless steel.

12. The chemical solution-housing article according to claim 10, wherein the nonmetallic material is at least one selected from the group consisting of polyethylene resins, polypropylene resins, polyethylene-polypropylene resins, tetrafluoroethylene resins, tetrafluoroethylene-perfluoroalkyl vinyl ether copolymers, tetrafluoroethylene-hexafluoropropylene copolymer resins, tetrafluoroethylene-ethylene copolymer resins, chlorotrifluoroethylene-ethylene copolymer resins, vinylidene fluoride resins, chlorotrifluoroethylene copolymer resins, and vinyl fluoride resins.

13. The chemical solution according to claim 2, wherein a total content of the propylene glycol monomethyl ether acetate and the organic acid is 99.5% by mass or more based on the total mass of the chemical solution.

14. The chemical solution according to claim 2, wherein the organic acid includes at least one selected from the group consisting of formic acid, acetic acid, propionic acid, butyric acid, glycolic acid, and lactic acid.

15. The chemical solution according to claim 2, further comprising Pb atoms,
wherein a content of the Pb atoms is 0.001 to 10 ppt by mass based on the total mass of the chemical solution.

16. The chemical solution according to claim 2, further comprising water,
wherein a content of the water is 0.0001 to 0.01% by mass based on the total mass of the chemical solution.

17. The chemical solution according to claim 2, wherein the content of the boron atoms is 0.05 to 50 ppt by mass based on the total mass of the chemical solution.

18. The chemical solution according to claim 2, wherein the content of the organic acid is 2 to 30% by mass based on the total mass of the chemical solution.

19. The chemical solution according to claim 1, wherein the chemical solution is used as a developer or a rinsing liquid.

20. A chemical solution-housing article comprising: a container; and the chemical solution according to claim 2, the chemical solution being housed in the container.
